(19) United States
(12) Patent Application Publication
(10) Pub. No.: US 2026/0164875 A1
(43) Pub. Date: Jun. 11, 2026

(54) OPTO-ELECTRONIC DEVICE AND METHOD OF MANUFACTURE

(71) Applicant: PORO TECHNOLOGIES LTD, Cambridge, Cambridgeshire (GB)

(72) Inventors: Tongtong ZHU, Cambridge (GB); Kunal KASHYAP, Cambridge (GB); Jia-Liang TU, Cambridge (GB); Kai-Jyun HUANG, Cambridge (GB)

(21) Appl. No.: 19/128,769

(22) PCT Filed: Nov. 10, 2023
(86) PCT No.: PCT/GB2023/052948

§ 371 Date: May 9, 2025

(30) Foreign Application Priority Data
Nov. 11, 2022 (GB) 2216889.2

(51) Int. Cl. H10H 29/14; H10H 20/01; H10H 20/841; H10H 20/852; H10H 20/857

(52) U.S. Cl. CPC H10H 29/14; H10H 20/017; H10H 20/018; H10H 20/034; H10H 20/0362; H10H 20/0364; H10H 20/841; H10H 20/852; H10H 20/857

(57) ABSTRACT

A device wafer comprising an opto-electronic device epitaxial structure on a substrate wafer, the device epitaxial structure comprising a porous region of III-nitride material; etching the device epitaxial structure into a plurality of device mesas; depositing a liner dielectric layer over the plurality of device mesas; forming a plurality of metal vias which extend through the liner dielectric layer to respective device mesas; and bonding the device wafer to a driver wafer comprising a driver circuit, so that the driver circuit is operatively coupled to the plurality of device mesas through the metal vias. An opto-electronic device comprises: a driver wafer comprising a driver circuit; a plurality of opto-electronic device mesas, each device mesa being configured to emit light out of a light-emitting-side of the device in response to a driving current from the driver circuit; a porous region of III-nitride material epitaxially connected to one or more of the device mesas; and a liner dielectric layer positioned between the driver wafer and the device mesas; each opto-electronic device mesa being operatively coupled to the driver circuit by a plurality of metal vias which extend through the liner dielectric layer.

The invention relates to an opto-electronic device, and a method of manufacturing an opto-electronic device. In particular the invention relates to a monolithic array of opto-electronic semiconductor devices having enhanced optical properties.

### BACKGROUND

III-V semiconductor materials are of particular interest for semiconductor device design, in particular the family of III-nitride semiconductor materials.

“III-V” semiconductors include binary, ternary and quaternary alloys of Group Ill elements, such as Ga, Al and In, with Group V elements, such as N, P, As and Sb, and are of great interest for a number of applications, including electronics and optoelectronics.

Of particular interest is the class of semiconductor materials known as “III-nitride” materials, which includes gallium nitride (GaN), indium nitride (InN) and aluminium nitride (AlN), along with their ternary and quaternary alloys. (Al, In)GaN is a term encompassing AlGaN, InGaN and GaN. III-nitride materials have not only achieved commercial success in solid-state lighting and power electronics, but also exhibit particular advantages for quantum light sources and light-matter interaction.

While a variety of III-nitride materials are commercially interesting, Gallium nitride (GaN) is widely regarded as one of the most important new semiconductor materials, and is of particular interest for a number of applications.

The present invention will be described primarily by reference to GaN and InGaN, but may advantageously be applicable to alternative III-nitride material combinations.

It is known that the introduction of pores into bulk III-nitrides, such as GaN can profoundly affect its material properties (optical, mechanical, electrical, and thermal, etc.). The possibility of tuning a wide range of material properties of GaN and III-nitride semiconductors by altering its porosity therefore makes porous GaN of great interest for optoelectronic applications.

The present inventors have also found that by using porous III-nitride material as a substrate, or template, for overgrowth of additional semiconductor layers and semiconductor devices, beneficial properties such as strain relaxation may be imparted to the overgrown devices by the porous layer. Following overgrowth of the desired semiconductor devices, however, it may be desirable to remove the semiconductor devices from the porous template, and to transfer the semiconductor devices to another carrier for fabrication into an electronic or optoelectronic device. It is an aim of the present invention to facilitate the safe and reliable removal of a semiconductor device from a substrate on which it has been grown.

In the present invention, regions or layers of semiconductor material may be porosified by electrochemical etching as set out in international patent applications PCT/GB2017/052895 (published as WO2019/063957) and PCT/GB2019/050213 (published as WO2019/145728).

### Problem to be Solved

Integration of different semiconductor devices, or components, into integrated end products, is a significant challenge in device fabrication.

In order to fabricate integrated semiconductor devices, in which multiple semiconductor devices of different types (for example multiple LEDs which emit different colours) are integrated onto a single device chip, it is typically necessary to grow the different semiconductor devices separately on their own template wafers, frequently using different semiconductor materials. The different semiconductor devices may then be removed from their growth templates and integrated onto a shared carrier wafer before processing the shared wafer into an end-product. For example it is frequently desirable to integrate multiple different LED types, which emit at different peak emission wavelengths, onto a single carrier wafer for fabrication into a multi-colour display device.

In order to avoid the complexity and cost of the separate growth, transfer and integration steps, it would be highly desirable to manufacture all of the required semiconductor devices monolithically, that is, on the same wafer template. Following epitaxial growth of the different semiconductor devices on the wafer, the required devices would thus already be positioned in the desired location on the shared wafer, where they are required to be for processing into an end-product. This would eliminate the need for the separate devices to be grown separately and transferred onto the shared wafer, and would therefore speed up device fabrication and reduce cost and complexity.

No viable monolithic integration method is yet commercially available for display applications or other light-emitting applications, because conventional III-nitride LEDs (standard LED, Mini-LED, Micro-LED, Nano-LED) can normally emit one colour at a time. This means that for a multi-colour light-emitting device, multiple single-colour LEDs, which have different epitaxial structures and are often formed from different semiconductor materials, have to be manufactured separately and then integrated onto a shared wafer.

For “large” (not mini, micro, or nano) LEDs, there are packaging innovations whereby three individual LEDs which emit red (R), green (G), and blue (B) can be packaged in a single die or package, or three packaged LEDs of R,G,B are mounted on the same PCB or circuit board. Such red, green and blue LEDs can be made from the same material system or different material systems. For example, the red, green and blue LEDs may be GaN-based or AlInGaP based, or GaAs based.

For Mini-LEDs, similarly to “large” LEDs, different colours of mini-LEDs may be packaged together using mass transfer or pick & place techniques, in which LED chips of different colour are integrated, mounted, or packaged on the same circuitry in a single die.

For MicroLEDs, due to the small sizes of MicroLED and the required pixel density, none of the above mentioned packaging, mounting or mass transfer/pick&place methods work well with reasonable yield and cost effectiveness.

The key problem is that one LED epitaxy, or one LED chip, can conventionally only produce LEDs which emit one colour, and heterogenous integration of multiple separate chips is already difficult and complex. Added to this, red and blue-green LEDs are typically grown from different semiconductor materials, which require different lift-off processing and make integration of different colours difficult.

Efforts have been made to get all three colours RGB (red, green and blue) LEDs demonstrated on the same substrate/wafer, namely using:
1. Selective area epitaxy or nanowire/nanorod/nanopyramids/nanoplalets method—either by varying the size of the mask/window (usually dielectric material as the mask, SiO₂ or SiNₓ) opening to confine a selective area for the LED epitaxy, and control the size of the nanostructures, hence the MQW and In % on the sidewall or surface of the nanostructures is controlled to emit different colours.
2. Stacking method, which uses either vertical stacking or lateral stacking:
   Vertical stacking—R,G,B LEDs (of any size) were fabricated (and R,G,B LED epitaxy/material can be obtained from same or different material systems), LEDs are processed and singulated, also the original substrate is lapped and polished, and thinned, and removed. Each colour of the LEDs are then stacked one on top of another to form a pixel. This process is very complex and yield is very low, considering all R,G,B LED epitaxy must done on foreign substrates, and the active LED pn junction is a very thin layer. These drawbacks make this method unfeasible for commercial device fabrication. In addition, this technique creates a problem with absorption of the light emitted by the LEDs, because the way the R,G,B LEDs are stacked vertically can cause problem for the optical performance and cross-talk of different pixels. Each colour LED has completely different optical and electrical characteristics, and each LEDs needs its own electrical contacts, making this technique even more difficult. Overall, the vertical stacking integration process is extremely complex and may be unsuitable at least for display applications.
   Lateral stacking—In lateral stacking integration, somewhat similarly to mass transfer processes, each R,G,B LED will need to be stacked/transferred side-by-side in a sub-pixel format laterally, one colour after another. This technique leads to the same problems with complex processing, low yield, and drawbacks created by combining different LEDs having different characteristics.

The monolithic integration of RGB LEDs on the same wafer therefore faces a number of challenges, and require improvement in several ways. Yield loss in existing techniques creates a high manufacture cost. It would be desirable to create monolithically integrated devices using a simple epitaxy, with no transfer/stacking/selective area epitaxy required, as this would result in lower cost and higher yield of integrated end-products. High performance is required for display applications, as well as colour uniformity. For display applications, system integration and power management it would also be highly beneficial for the different semiconductor devices on the integrated wafer to have similar optical and/or electrical characteristics.

It is an aim of the present invention to address these issues, and to provide a method of manufacture with high yield and simple processing throughout the entire display fabrication process.

To simplify LED manufacturing processes and reduce mass production cost, Poro Technologies has released LEDs featuring embedded nanoporous architecture, which enables GaN-based LEDs to output full color range. These LEDs are described, for example, in international patent applications PCT/GB2021/050152 (published as WO2021/148808) and PCT/GB2021/052020 (published as WO2022/029434).

### SUMMARY OF INVENTION

In the present invention, an embedded nanoporous architecture enables monolithic integration of multiple opto-electronic semiconductor devices on a single wafer. For example the present invention enables monolithic integration of multiple LEDs having different emission colours (different peak emission wavelengths) on a single semiconductor wafer.

The present invention is defined in the independent claims, to which reference should now be made. Preferred or advantageous features of the invention are set out in the dependent sub-claims.

In a first aspect of the present invention there is provided a method of manufacturing an opto-electronic device. The method of manufacturing an opto-electronic device may be a method of integrating an opto-electronic device with a driving circuit.

The first aspect of the invention provides a method of manufacturing an opto-electronic device comprising the steps of:
providing a device wafer comprising an opto-electronic device epitaxial structure on a substrate wafer, the device epitaxial structure comprising a porous region of III-nitride material;
etching the device epitaxial structure into a plurality of device mesas;
depositing a liner dielectric layer over the plurality of device mesas;
forming a plurality of metal vias which extend through the liner dielectric layer to respective device mesas; and
bonding the device wafer to a driver wafer comprising a driver circuit, so that the driver circuit is operatively coupled to the plurality of device mesas through the metal vias.

The liner dielectric layer may comprise a material which is compatible with a CMOS driver. The liner dielectric layer may be made of SiO₂ or silicon nitride, SiNs, for example. The device wafer is preferably bonded to the driver wafer so that each metal via is electrically coupled to its own CMOS driver in the driver circuit.

The method preferably comprises the step of depositing dielectric filler material over the plurality of device mesas after the liner dielectric layer has been deposited. The dielectric filler material may advantageously be planarized, or flattened, to provide a planar upper surface on the device wafer. The metal vias may then be formed so that they extend from the planar upper surface of the device wafer, through the dielectric filler material and the liner dielectric layer to respective device mesas. The planar upper surface of the device wafer may then be bonded to the driver wafer, which preferably has its own planar upper surface.

### Embodiment 1

In a preferred first embodiment of the invention, the method comprises the step of depositing dielectric filler material directly over the liner dielectric layer. The method may thus involve depositing the liner dielectric layer over the device mesas, and then depositing a planarized layer of dielectric filler material over the liner dielectric layer.

The step of forming the metal vias may then comprise etching a plurality of channels from the planar upper surface of the wafer, through the dielectric filler material and the liner dielectric layer, to the device mesas. The method then comprises depositing metal in the plurality of channels to form metal vias. The metal vias thus form electrically-conductive pathways between the device mesas and the planar upper surface of the wafer.

Etching through the liner dielectric layer involves forming an opening through the liner dielectric layer which exposes a contact area of the respective device mesa. This exposed contact area is the area of the device mesa which is in electrical contact with the metal via once the metal has been deposited. The sizes of the contact areas, and thus the lateral size of the metal vias, may be controlled by varying the width of the channels etched through the dielectric filler material and the liner dielectric layer.

The size (lateral area) of the opening through the liner dielectric layer controls the area of the exposed portion of the device mesa. This in turn will determine the area over which the device mesa is in contact with the metal contact. The opening through the liner dielectric layer provides a contact area because in use, the driving current provided to the device mesa by the driver circuit will have to pass through this contact area to reach the device mesa. Forcing a given magnitude of driving current to flow through a small contact area will create a high current density in the region of the device mesa near the contact area, while applying the same magnitude of driving current through a larger contact area will allow the driving current to spread over the larger contact area so that the device mesa experiences a lower current density. The size of the contact area and the magnitude of the driving current thus determine the driving current density experienced by the device mesa in use. In a particularly preferred embodiment of the invention discussed further below, the device mesas are variable-wavelength LEDs which respond to different driving current densities by emitting different peak emission wavelengths. Controlling the contact areas on the device mesas may thus advantageously provide an additional way of controlling the driving current densities provided to the variable-wavelength LEDs, and as a result controlling the peak emission wavelength of those LEDS.

The contact area on each device mesa may be controlled by controlling the size of the opening through the liner dielectric layer, which in turn controls the area of the metal contact formed in the opening. By controlling the contact area the driving current density experienced by the device mesa under a given driving current may be controlled.

The sizes of the contact areas may vary between device mesas. For example a first contact area may be formed on a first device mesa by etching an opening in the liner dielectric layer to expose a portion of the first device mesa, the size of the exposed portion having the first contact area. A second contact area may be formed on a second device mesa by etching an opening in the liner dielectric layer to expose a portion of the second device mesa, the size of the exposed portion having the second contact area. The size of the second contact area may be different from the size of the first contact area. By providing contact areas having different sizes on different device mesas, it is possible to control the driving current densities which will be experienced by those device mesas. If the contact areas have different sizes, the first and second device mesas will experience a different driving current density even if the same magnitude of driving current is provided to both device mesas by the driving circuit.

Once the metal vias have been formed, the planar upper surface of the wafer is then bonded to the device wafer, so that the metal vias are aligned with and contact respective metal vias or pads of the driver circuit, to create an electrical connection between the driver circuit and the respective device mesas.

### Embodiment 2

In a preferred second embodiment of the invention, the method comprises the step of depositing a reflective layer over the plurality of device mesas following the step of depositing the liner dielectric layer over the plurality of device mesas. The reflective layer is preferably a metal layer. The liner dielectric is deposited over the edges and sidewalls of the device mesas to electrically isolate the device mesas from the subsequently-deposited reflective layer. The reflective layer may advantageously cover the sidewalls and tops of the device mesas, to reflect any light emitted in directions other than the intended light-emitting direction.

The reflective layer may be formed by depositing a layer of metal over the liner dielectric layer.

The reflective layer may be formed by depositing metal over the liner dielectric layer as a filler material to fill trenches between the device mesas. The metal may thus act both as a filler material and a reflective layer which surrounds the device mesas. The method may then comprise the step of planarizing the metal to form a planar surface which is level with the liner dielectric layer that extends over the top of the device mesas.

The method may optionally comprise the steps of depositing a reflective layer and then depositing metal filler material over the reflective layer, and planarizing the metal filler material level with the liner dielectric layer extending over the device mesas prior to the step of depositing dielectric filler material.

Preferably a layer of dielectric filler material is deposited over the planarized metal surface, so that the dielectric filler material provides a planar upper surface of the device wafer, and metal vias can be formed through the dielectric filler material to connect to the respective device mesas.

Prior to depositing the reflective layer, the method may comprise the step of etching a plurality of openings through the liner dielectric layer, over the plurality of device mesas, so that a portion of each device mesa is exposed through an opening in the liner dielectric layer before the reflective layer and/or metal filler is deposited. When the reflective layer and/or metal filler is deposited over the liner dielectric, the metal fills the openings in the liner dielectric, to form a metal contact which extends through the liner dielectric and contacts the exposed portion of each device mesa.

As discussed above, the size of the contact areas on the device mesas may be varied, and different sizes of contact areas may be formed on different device mesas.

In addition to forming the openings to expose the device mesas, openings through the dielectric layer may also be formed in other locations on the device wafer, for example in trenches, to expose portions of the material beneath the liner dielectric.

The method may preferably comprise the step of depositing a metal landing, or a metal pad, over each of the openings in the liner dielectric layer, the metal pads forming electrical contacts for each of the device mesas.

Dielectric filler material is preferably deposited over the device wafer after the metal pads have been deposited. The dielectric filler material advantageously provides a planar upper surface on the device wafer, optionally after an additional step of planarizing or flattening the dielectric filler material.

Once the dielectric filler material has been deposited, the metal vias are formed so that they extend from the planar upper surface of the device wafer, through the dielectric filler material to respective metal pads. The planar upper surface of the device wafer is then bonded to the driver wafer so that the metal vias are electrically connected to corresponding conductive pads or vias on the driver wafer.

The step of forming the metal vias may comprise etching a plurality of channels from the planar upper surface of the wafer, through the dielectric filler material, to the metal pads, and then depositing metal in the plurality of channels to form the metal vias.

### Common Features

The following features apply to both the first and second embodiments discussed above.

The step of etching the device epitaxial structure into a plurality of device mesas may comprise etching trenches into the device epitaxial structure. The etching may be controlled, using conventional semiconductor processing techniques, to determine the depth to which the trenches are etched into the epitaxial structure.

In order to form discrete device mesas, each of which are separately operable as opto-electronic semiconductor devices, the trenches are preferably etched to a depth below the depth of the active light-emitting region in the device epitaxial structure. Thus each discrete device mesa preferably has its own light-emitting region.

Trenches may be etched through the entire depth of the device epitaxial structure and any semiconductor underlayers, so that the trenches extend down to the device substrate, and device mesas on opposite sides of the trench are electrically-isolated from one another.

Alternatively trenches may be etched only part-way through the device epitaxial structure and any semiconductor underlayers, so that some intact epitaxial layers extend under the trench to connect device mesas on either side of the trench. For example trenches may be etched to the level of the n-doped, or p-doped layer of the device epitaxial structure which is below (on the substrate-side) of the active light-emitting region. Alternatively, the device mesas may be overgrown on one or more conductive layers of semiconductor material which extend below the level of the trench and provides an electrical pathway between device mesas on either side of the trench.

The step of etching the device epitaxial structure into a plurality of device mesas may comprise performing an isolation etch, in which an isolation trench is etched through the entire depth of the device epitaxial structure, to electrically isolate device mesas on opposite sides of the isolation trench. The isolation trench is preferably etched through all epitaxial layers, down to the substrate wafer.

One or more metal vias may be formed in an isolation trench, so that the isolation trench metal via extends from the planar wafer surface, through the dielectric filler material and the liner dielectric layer, to the substrate wafer.

In some preferred embodiments, the isolation trench may be filled with metal filler, for example when the reflective layer is deposited as discussed above. One or more metal pads may be positioned on the metal-filled isolation trench. The isolation trench metal via may extend from the planar wafer surface, through a dielectric filler material, to a metal pad positioned in the isolation trench or on the metal pad which fills the isolation trench.

The step of etching the device epitaxial structure into a plurality of device mesas may comprise performing a mesa etch, in which a mesa trench is etched through a partial depth of the device epitaxial structure. The mesa trench preferably does not extend through at least one electrically conductive layer of the device wafer, such that device mesas on either side of the mesa trench are not electrically isolated from one another.

One or more metal vias may be formed in a mesa trench. The mesa trench metal via may extend from the planar wafer surface, through the dielectric filler material and the liner dielectric layer, to the epitaxial layer beneath the liner dielectric. The epitaxial layer beneath the liner dielectric layer may be an n-type or p-type layer of the device epitaxial structure, or a conductive connecting layer which is positioned between the device epitaxial structure and the substrate wafer, or a porous layer of III-nitride material which is positioned between the device epitaxial structure and the substrate wafer.

One or more openings may be etched through the liner dielectric layer in a mesa trench to expose a layer of the device epitaxial structure below the liner dielectric layer. This has the advantage of providing a common electrical connection for driver circuitry after bonding, which may improve circuitry control and functionality. The common electrical connection may be a cathode or an anode.

The mesa trench metal via may extend from the planar wafer surface, through the dielectric filler material and the liner dielectric layer, to a layer of device epitaxial structure below the mesa trench.

The method may comprise the step of depositing, over the metal vias, a plurality of metal pads for routing and bonding to the driver wafer.

The device epitaxial structure may be etched so that the device mesas are non-uniform in lateral size. By controlling the separation of the trenches etched into the device epitaxial structure, the lateral size of each individual device mesa may be controlled. It may be desirable to form some device mesas with a larger lateral area than others, in order to control the lateral area of the light-emitting area. By controlling the lateral area of the light-emitting area of a device mesa, the luminosity of that device mesa may be controlled, and the current density of driving current passing through that device mesa may be controlled.

The device epitaxial structure may be etched so that the device mesas are not uniformly spaced on the device wafer. The relative positions of the device mesas on the device wafer may be determined by controlling the separation of the trenches etched into the device epitaxial structure, and the widths of the trenches etched into the device epitaxial structure. Thus the lateral separation between adjacent device mesas may be controlled by varying the widths of the trenches separating those mesas. It may be desirable for the spacing between the device mesas to be non-uniform in order to give a desired result in the optical emission characteristics of the resulting opto-electronic device. For example it may be desirable to position a first group of device mesas closely spaced together, with narrow trenches therebetween, so that the first group of device mesas forms a first display pixel, with each of the first group of device mesas acting as a subpixel of that display pixel. It may then be desirable to form a second group of device mesas on the same wafer, the second group of device mesas acting as a second display pixel. The separation between the first device pixel and the second device pixel may then be controlled by varying the width of the trench separating the two groups of subpixels.

Using the present invention the lateral size and shape of the device mesas, and the separation of the device mesas, may be controlled and varied by controlling the positioning, width and number of trenches etched into the device epitaxial structure. This creates a huge range of possibilities for the design of the resulting opto-electronic device, which have not previously been achievable using the inflexible pick-and-place integration methods of the prior art.

Some preferred embodiments of the method comprise the step of removing the substrate wafer to form a light-emitting-side of the device after the device wafer is bonded to the driver wafer. The device wafer is inverted in order to bond the formerly upper surface of the device wafer to the upper surface of the driver wafer. The substrate wafer which during manufacture of the device wafer forms the bottom surface of the device wafer, is then removed, for example by lapping or thinning, and the side of the combined device from which the substrate wafer is removed becomes the light-emitting-side of the device.

In embodiments in which some or all of the isolation trenches have been filled with metal, the method may comprise the step of etching an opening through the liner dielectric layer after removal of the substrate wafer, to expose the metal in the isolation trench. The exposed metal in the isolation trench may then advantageously provide a metal pad for wire bonding. Specifically, the metal pad may improve the ease with which a subsequent wire bonding step is achieved.

Alternatively, where the isolation trenches are not filled with metal, the method may comprise the step of depositing a metal pad over an isolation trench after removal of the substrate wafer. The metal pad is in electrical connection with one or more metal vias extending through the liner dielectric layer and any other intermediate layers of the device, to the driver wafer.

The method may comprise the step of depositing one or more micro-lenses over some or all of the device mesas on the light-emitting-side of the device. Micro-lenses can improve the directionality of light emitted by the device. This is particularly advantageous in a device comprising a micro-LED, in which a light emission angle is wide and Lambertian. This is also particularly advantageous in applications such as augmented reality or virtual reality displays, and in head-up display or near eye applications. In such applications, use of a micro-lens can facilitate collimation or use of waveguides and module optics. Use of a micro-lens can also increase brightness of a micro-LED, or increase the measured value of Candela per square metre.

As discussed further below in relation to the second aspect of the invention, the device wafer preferably comprises a porous region of III-nitride material. Preferably the device wafer comprises a porous region of III-nitride material positioned between the device epitaxial structure and the substrate wafer, and/or a porous region of III-nitride material positioned in the device epitaxial structure above or below the light-emitting region.

In particularly preferred embodiments, the device epitaxial structure is an LED structure. Each device mesa is therefore an LED. Preferably each device may be a mini-LED, a micro-LED or a nano-LED structure as discussed further below in relation to the second aspect of the invention.

Particularly preferably the method comprises the step of etching a variable-wavelength LED structure into a plurality of device mesas. In this case, the driver circuit is preferably configured to provide a variable-magnitude driving current to each of the device mesas.

The method may comprise the step of etching a variable-wavelength LED structure into a plurality of device mesas having a plurality of lateral sizes. For example etching trenches into a variable-wavelength LED structure to form a first device mesa having a first lateral area, and a second device mesa having a second lateral area different from the first lateral area. The first and second mesas may be first and second variable-wavelength LED subpixels, with the pair of first and second device mesas forming a display pixel. Optionally the variable-wavelength LED epitaxial device structure may be etched to form a third device mesa having a third lateral area different from the first and second lateral areas, the first, second and third device mesas forming three subpixels which together provide a display pixel.

The method may comprise the step of etching the device epitaxial structure into a plurality of display pixels, each display pixel comprising one or more device mesas. For example a single variable-wavelength LED device mesa may form a display pixel which can emit at different peak wavelengths by varying the driving current provided by the driver circuit. In another embodiment, a pair of first and second variable-wavelength LED device mesas may act as two subpixels which combine to create a device pixel, each of the two subpixels being independently controllable by the driver circuit to emit a peak wavelength which is tuned by the driving current provided to the subpixel by the driver circuit. In another embodiment, three device mesas—first, second and third variable-wavelength LED device mesas—may act as three subpixels which combine to create a device pixel, each of the three subpixels being independently controllable by the driver circuit to emit a peak wavelength which is tuned by the driving current provided to the subpixel by the driver circuit.

The driver circuit may be configured to control the power or the current or the voltage of the power supply to each variable-wavelength LED device mesa. The driver circuit may be configured to provide a pulsed, or CW, or quasi-CW power supply to the variable-wavelength LED device mesas.

### Method of Manufacture of Variable-Wavelength LED

A variable-wavelength LED epitaxial device structure may be manufactured by a method comprising the step of growing:
an n-doped portion;
a p-doped portion; and
a light-emitting region located between the n-doped portion and a p-doped portion, the light-emitting region comprising a light-emitting layer which emits light at a peak emission wavelength under electrical bias thereacross.

The method may comprise the step of overgrowing the n-doped portion, the p-doped portion and the light-emitting region over a porous region of III-nitride material.

The method may comprise the step of forming a porous region of III-nitride material in at least one of the n-doped portion or the p-doped portion, and forming the light-emitting region over a porous region of III-nitride material.

The method may optionally comprise the step of removing the porous region from the LED structure (the n-doped portion, the p-doped portion and the light-emitting region) after the n-doped portion, the p-doped portion and the light-emitting region have been formed.

The light-emitting layer may emit light at a peak emission wavelength between 400 and 800 nm, or between 450-800 nm, or between 500 and 800 nm, or between 550 and 800 nm, or between 610 and 800 nm under electrical bias thereacross.

The LED structure, including the n-doped portion, the p-doped portion, and the light-emitting region, may be an LED structure for emitting at a wavelength lower than the peak emission wavelength of the LED, so that the porous region of III-nitride material red-shifts the emission wavelength of the light-emitting region to the peak emission wavelength.

The n-doped portion, the p-doped portion and the light-emitting region are preferably formed from III-nitride semiconductor material.

In a preferred embodiment, the light-emitting region may comprise a light-emitting indium gallium nitride layer for emitting at a peak wavelength of 500nm-550 nm or 550 nm-600 nm,
wherein overgrowth on the porous region of III-nitride material shifts the emission wavelength of the light-emitting region to a peak wavelength between 600 and 750 nm under electrical bias.

The light-emitting region may comprise a light-emitting indium gallium nitride layer for emitting at a peak wavelength of 500-550 nm, or 500-580 nm, or 510 to 570 nm, or 530 nm to 560 nm, or 550 nm to 600 nm. The light-emitting indium gallium nitride layer may be one or more layers known to emit at these wavelengths when grown in conventional LEDs, for example on non-porous GaN substrates. However, the inventors have found that growing conventional yellow or green LED structures over a porous III-nitride layer leads to an LED that emits at a peak wavelength between 600 and 750 nm under electrical bias.

The method may comprise the step of growing a yellow or green LED structure over a porous region of III-nitride material.

In preferred embodiments, the light emitting layer is a light-emitting indium gallium nitride layer. The LED preferably also comprises a region of GaN material. Due to the lattice mismatch between GaN and InGaN, the stress relaxation effect created by the porous region is particularly advantageous.

The method may comprise the step of forming the light emitting active region with carrier localisation centres in the quantum wells (which are preferably InGaN QWs). such as multiple types of QW region with different Indium composition and well width and quantum barriers, non-uniform, or fragmented, or broken, or gappy, or discontinuous quantum wells which would result in fluctuation in the well width, InGaN quantum dots or nanostructures, quantum wells formed on polar, semi-polar or non-polar facets.

The method may comprise the step of forming a plurality of quantum wells (QWs), in which the quantum wells are non-uniform, fragmented, or discontinuous.

The plurality of QWs may comprise fluctuations in indium composition, and/or well width fluctuations.

The method may comprise the step of forming one or more v-shaped pits in the LED structure, so that the v-shaped pit extends through the thickness of the light-emitting region. Preferably the method comprises the step of forming at least 0.1 v-shaped pits per square micrometre, or at least 1 v-shaped pits per square micrometre, or at least 2 v-shaped pits per square micrometre. Preferably the method comprises the step of forming a density of v-shaped pits in the light-emitting region of at least 1×10⁷/cm², for example at least 5×10⁷/cm² or at least 1×10⁸/cm², for example a density of v-shaped pits of 1×10⁷/cm² to 5×10⁹/cm². Preferably the method comprises the step of forming a density of v-shaped pits in the light-emitting region of less than 5×10⁹/cm 2, for example a density of v-shaped pits of less than 1×10⁹/cm² or less than 5×10⁸/cm².

V-shaped pits are a phenomenon known in the art of epitaxial semiconductor growth, and methods of growing v-shaped pits in semiconductor structures are known in the art. For example, v-shaped pits and their growth are described in the prior art in The effect of nanometre-scale V-pits on electronic and optical properties and efficiency droop of GaN-based green light-emitting Diodes; Zhou et al; Scientific Reports|(2018) 8:11053|DOI:10.1038/s41598-018-29440-4.

V-shaped pits may be grown in the semiconductor structure so that they terminate in a layer below the active light-emitting region. This means that the v-shaped pits must extend through the thickness of the active light-emitting region.

V-shaped pits may be grown from threading dislocations in the semiconductor structure by controlling the growth conditions during epitaxial deposition of layers above a layer containing a threading dislocation. The threading dislocations are perpetuated upwards through the structure as additional layers are grown over layers containing a threading dislocation, and by controlling growth conditions the dislocation is widened into a v-shaped pit.

V-shaped pits can alternatively be grown using 3-dimensional epitaxial growth modes. 3D epitaxial deposition techniques are known in the art and are typically used to grow “islands” or “pyramids” of semiconductor material on a template. By controlling deposition of the LED structure using 3D epitaxial deposition techniques, v-shaped pits can be artificially grown in desired locations, with no need for a threading dislocation to be present to “seed” the formation of the v-shaped pit. By using this deposition control, the bottom (nadir) of the pit may be created at a desired location in the structure—both a desired lateral position and a desired height in the structure, for example in a particular layer of the semiconductor structure below the active light-emitting region.

The bottom of the v-shaped pit may be located in the connecting layer of the semiconductor structure. The connecting layer may be positioned between the porous region and the n-doped portion.

The bottom of the v-shaped pit may be located in a pre-strain layer of the semiconductor structure. The pre-strain layer may be positioned above the n-doped portion and below the light-emitting region.

Preferably the LED comprises a plurality of v-shaped pits which extend through the active light-emitting region.

Both the density and size (the depth) of the v-shaped pits may be controlled. The size of the V-pits can be controlled by the position and the growth conditions of the pre-strain layer and the low-temperature nGaN layer where the pits started.

Quantum wells (QWs) in the active light-emitting region may be deposited so that the quantum wells are continuous and/or of uniform thickness. Alternatively quantum wells (QWs) in the active light-emitting region may be deposited so that the quantum wells are fragmented, or discontinuous.

### Manufacturing Steps

The n-type region, the light-emitting region and the p-type region (which may be called the LED structure) are preferably grown over a semiconductor template which contains the porous region. The semiconductor template may also contain a number of layers of semiconductor material arranged to provide a suitable substrate for the overgrowth of the LED structure.

The method may comprise the first step of electrochemically porosifying a layer of III-nitride material, to form the porous region of III-nitride material. This may be achieved using a wafer scale porosification process as set out in international patent applications PCT/GB2017/052895 (published as WO2019/063957) and PCT/GB2019/050213 (published as WO2019/145728).

The method may preferably comprise the step of forming the porous region of III-nitride material by electrochemical porosification through a non-porous layer of III-nitride material, such that the non-porous layer of III-nitride material forms a non-porous intermediate layer. The non-porous intermediate layer may advantageously provide a smooth surface for overgrowth of further layers, such as one or more connecting layers of III-nitride material.

The porous region may be formed by porosifying one or more layers or regions of III-nitride material on a substrate. The substrate may be Silicon, Sapphire, SiC, β-Ga2O3. The crystal orientation of the substrates can be polar, semi-polar or non-polar orientation. The substrate thickness may typically vary between 100 μm and 1500 μm.

The porous region may be a porous layer, such that the method comprises the step of overgrowing, over a porous layer of III-nitride material: an n-doped portion; a p-doped portion; and an LED light-emitting region. Preferably the porous region may be a porous layer that is continuously porous, for example formed from a continuous layer of porous III-nitride material.

The porous region may comprise a plurality of porous layers, and optionally a plurality of non-porous layers. In preferred embodiments of the invention, the porous region is a stack of alternating porous and non-porous layers, with the top surface of the stack defining the top of the porous region, and the bottom surface of the stack defining the bottom of the porous region.

Alternatively the porous region may be a layer of III-nitride material that contains one or more porous regions, for example one or more porous regions in an otherwise non-porous layer of III-nitride material.

In preferred embodiments, the porous region, or porous layer, may have a lateral dimension (width or length) equivalent to that of the substrate wafer on which the porous layer or region is grown. For example, conventional substrate wafer sizes may have a variety of sizes, such as 1 cm², or 2 inch, 4 inch, 6 inch, 8 inch, 12 inch, or 16 inch diameter. By patterning one or more layers and/or depositing regions of different charge carrier concentrations in the same layer, however, smaller porous regions can be formed that do not span the entire substrate. The lateral dimensions of the porous layer or region may therefore vary from around 1/10 of a pixel (for example 0.1 μm), up to the lateral dimensions of the substrate itself.

Prior to the porosification step, a doped region of n-doped III-nitride semiconductor material, preferably containing a layer, or stack of layers, may be deposited on a substrate. The III-nitride layer(s) may contain one or a combination of these elements: Al, Ga, In (ternary of quaternary layer). The thickness of the III-nitride stack is preferably between 10-4000 nm. The III-nitride region may have a doping concentration between 1×10¹⁷ cm⁻³-5×10²⁰ cm⁻³.

Preferably an intermediate layer of undoped III-nitride material is deposited over the doped material before it is porosified. The intermediate layer preferably has a thickness of between 1 nm and 3000 nm, preferably between 5 nm and 2000 nm. As the intermediate layer is undoped, it remains non-porous after the porosification step, which advantageously provides a good surface for epitaxial overgrowth of further layers of semiconductor.

In preferred embodiments, the doped region consists of an alternating stack of doped and undoped layers. In preferred embodiments the stack contains between 5-50 pairs of layers. The thickness of each highly doped layer may vary between 10 nm-200 nm and low-doped or undoped layers may have a thickness of between 5-180 nm.

As is known in the art, electrochemical porosification removes material from n-type doped regions of III-nitride materials, and creates empty pores in the semiconductor material.

In preferred embodiments, the LED structure is formed over a stack of multiple porous layers of III-nitride material. Thus, rather than being a single porous layer of III-nitride material, the porous region may be a stack of layers of III-nitride material in which at least some layers are porous. The stack of porous layers may preferably be a stack of alternating porous and non-porous layers.

The method may preferably comprise the step of depositing one or more connecting layers of III-nitride material on the surface of the intermediate layer of III-nitride material prior to overgrowing the n-doped region, the LED light-emitting region and the p-doped region on the connecting layer.

Alternatively, where there is no non-porous intermediate layer over the porous region, the method may comprise the step of depositing a connecting layer of III-nitride material onto the surface of the porous region of III-nitride material.

The method may comprise the further step of overgrowing the n-doped region, the LED light-emitting region and the p-doped region on the connecting layer.

### Opto-Electronic Device

According to a second aspect of the present invention there is provided an opto-electronic device comprising:
a driver wafer comprising a driver circuit;
a plurality of opto-electronic device mesas, each device mesa being configured to emit light out of a light-emitting-side of the device in response to a driving current from the driver circuit;
and
a liner dielectric layer positioned between the driver wafer and the device mesas;
each opto-electronic device mesa being operatively coupled to the driver circuit by a plurality of metal vias which extend through the liner dielectric layer.

The opto-electronic device is preferably a device manufactured by the method of the first aspect of the invention. Any features described in relation to the first aspect are therefore applicable to the second aspect of the invention and vice versa.

The opto-electronic device may comprise a porous region of III-nitride material epitaxially connected to one or more of the device mesas. Alternatively, the porous material may have been removed during manufacture, for example when the growth substrate is removed from the epitaxial structure.

The device may comprise a dielectric filler material positioned between the driver wafer and the liner dielectric layer, in which the metal vias extend through the dielectric filler material and the liner dielectric layer.

The opto-electronic device epitaxial structure preferably comprises an n-doped region, a p-doped region, and a light-emitting region arranged between the n-doped region and the p-doped region.

Particularly preferably, each device mesa has the same device epitaxial structure. As the device mesas are formed by etching a single epitaxial structure into a plurality of separate device mesas, the composition and layer arrangement of each of the device mesas will be the same.

Although the epitaxial layer design of each device mesa is the same, different device mesas may optionally have different lateral sizes, such that different device mesas have light-emitting areas of different sizes. This may be accomplished by varying the spacing of trenches to control the lateral size of the mesas formed between etched trenches.

The device may comprise two or more device mesas which are electrically connected to one another via a shared conductive layer of semiconductor material. These electrically-connected device mesas may be separated by mesa barriers positioned between device mesas, in which the mesa barriers do not extend through the shared conductive layer.

The shared conductive layer may be an n-type layer or a p-type layer forming part of the device epitaxial structure of the device mesas, or a doped connecting layer which extends across the device above the mesa barriers and is connected to multiple device mesas, or a porous layer of semiconductor material which is positioned above the mesa barriers and is connected to multiple device mesas.

Mesa barriers are formed where trenches etched into the device epitaxial structure during manufacture have been filled with material to convert the empty trench into an electrically-insulating barrier. The mesa barriers may be formed from dielectric filler material covered by the liner dielectric layer. Alternatively the mesa barriers may be formed from metal covered by the liner dielectric layer.

The device may comprise two or more device mesas which are electrically isolated from one another. Electrically-isolated device mesas may be separated by electrically-insulating isolation barriers. Similarly to the mesa barriers, isolation barriers are formed where isolation trenches etched into the device epitaxial structure during manufacture have been filled with material to convert the empty isolation trench into an electrically-insulating isolation barrier between device mesas. The isolation barriers may be formed from dielectric filler material covered by the liner dielectric layer. Alternatively the isolation barriers may be formed from a metal pad surrounded by the liner dielectric layer.

The device may comprise a reflective layer adjacent to the liner dielectric layer, the reflective layer being positioned between the liner dielectric layer and the driver wafer. The reflective layer preferably surrounds the sidewalls of the device mesas to form a sidewall reflection structure which is configured to reflect emitted light towards the light-emitting-side of the device.

In some preferred embodiments, the device may comprise a plurality of micro-lenses arranged on the light-emitting-side of the device, each micro-lens being positioned over a respective device mesa and configured to transmit light emitted by the underlying opto-electronic device mesa.

The device may comprise one or more metal pads on the light-emitting side of the device, each metal pad being electrically connected to the driver circuit by one or more metal vias. Such metal pads may advantageously provide a convenient location for wire bonding. The metal pads may be positioned on the surface of the light-emitting-side of the device, or alternatively the metal pads may form part of isolation barriers positioned between device mesas below the surface of the light-emitting-side of the device.

Preferably each device mesa is electrically coupled to its own CMOS driver in the driver circuit, such that each device mesa is independently driveable by the driver circuit.

### Porous Regions

The opto-electronic device preferably comprises one or more porous regions of III-nitride material.

The n-type region, the light-emitting region and the p-type region (which may be called the LED structure, or LED diode structure) are preferably grown over a semiconductor template which contains the porous region. The semiconductor template may also contain a number of layers of semiconductor material arranged to provide a suitable substrate for the overgrowth of the LED structure.

The porous region may be a porous layer, such that the light emitting diode comprises a porous layer of III-nitride material. Preferably the porous region may be a porous layer that is continuously porous, for example formed from a continuous layer of porous III-nitride material.

The porous region may comprise a plurality of porous layers, and optionally a plurality of non-porous layers. In preferred embodiments of the invention, the porous region is a stack of alternating porous and non-porous layers, with the top surface of the stack defining the top of the porous region, and the bottom surface of the stack defining the bottom of the porous region. The light-emitting region may be formed over a porous region comprising a stack of porous layers of III-nitride material.

Each device mesa may comprise its own porous region of III-nitride material, or alternatively a shared porous region may be epitaxially connected to a plurality of the device mesas. For example a porous region may extend over one or more mesa barriers, between the device mesas and the light-emitting-surface of the device.

The device may comprise a porous region of III-nitride material positioned over the device mesas, positioned between some or all of the device mesas and the light-emitting surface of the device.

The porous region may take a variety of forms, and may perform a variety of functions to enhance the optical characteristics of the opto-electronic device. For example, the porous region may be configured to improve light extraction from the device by acting as an anti-reflection layer, or a reflective layer, or as a wavelength-specific optical filter. The porous region may provide a variety of optical engineering functions to the device, and may be configured to provide DBRs, alternating layers, optical filers, reflectors, band pass, band stop filters, and/or mirrors.

In some preferred embodiments, the device wafer comprises a distributed Bragg reflector (DBR) positioned over the device mesas, such that the device mesas are arranged between the DBR and the light-emitting surface of the device. The DBR comprises a plurality of porous layers of III-nitride material, and may be configured to act as an optical filter which transmits a first emitted wavelength of light out of the light-emitting side of the device, and reflects other emitted wavelengths. The DBR may thus act as a wavelength-specific optical filter, which allows transmission of only selected wavelengths depending on the layer thickness of the layered DBR structure.

The porous region may be configured to act as a wavelength-selective transmission layer on the light-emitting side of the device, such that the wavelength-selective transmission layer allows some wavelengths to be transmitted therethrough, while blocking transmission of other wavelengths.

The device may comprise a porous region of III-nitride material positioned between some or all of the device mesas and the driver wafer. For example each device mesa may comprise a porous region. The porous region may be part of the device epitaxial structure. For example the n-type layer or the p-type layer of the device epitaxial structure may be porous, or a porous layer may be positioned in another epitaxial layer in the device mesas. In another preferred embodiment, the device may comprise a distributed Bragg reflector (DBR) positioned between the device mesas and the driver wafer. The DBR comprises a plurality of porous layers of III-nitride material, and is configured to reflect emitted light out of the light-emitting-side of the device. This may advantageously improve light-extraction efficiency by reflecting emitted light which would otherwise be lost and not directed out of the light-emitting side of the device.

The or each porous region in the device may have the same thickness and porosity. For example the entire device epitaxial structure, from which each device mesa is etched, may have been formed over the same porous layer of III-nitride material.

Alternatively, the device may comprise a plurality of porous regions having different thicknesses and/or porosities, such that different device mesas are aligned with different porous regions.

The porosity characteristics of the porous region may vary in different lateral locations on the device. For example a first porous region may have a first thickness, and a second porous region in a separate lateral location in the device may have a second thickness different from the first thickness. The optical behaviour of the porous regions may thus be different in different locations on the device, and for different opto-electronic device mesas. The device may comprise a multi-zone optical filter comprising a plurality of porous regions of different thicknesses, the respective porous regions of different thicknesses being positioned over different device mesas.

### Opto-Electronic Device Types

In particularly preferred embodiments the device is a display device, and each device mesa is an LED. Preferably each device mesa is a mini-LED, a micro-LED or a nano-LED.

The device may comprise a monolithic array of LED device mesas, in which each device mesa is an LED subpixel, and in which groups of LED device mesas form a device pixel.

The LED epitaxial device structure which is shared by each of the device mesas may comprise a light-emitting region which preferably comprises a multiple quantum well (MQW) containing a plurality of quantum wells (QWs), or quantum dots, quantum wires, or other quantum nanostructures.

An LED comprises an n-doped portion, a p-doped portion, and a light-emitting region located between the n-doped portion and a p-doped portion, the light-emitting region comprising a light-emitting layer which emits light at a peak emission wavelength under electrical bias thereacross.

The light-emitting region, and/or the LED, may have lateral dimensions (width and length) of greater than 100 um and less than 300 μm. In this case, the LED may be termed a “mini-LED”. In preferred embodiments, the mini-LED may be square or circular or square with circular corners and have dimensions such as 300 μm×300 μm, 200 μm×200 μm, 100 μm×100 μm.

The light-emitting region, and/or the LED, may alternatively have lateral dimensions (width and length) of less than 100 μm. In this case, the LED may be termed a “micro-LED”. The micro-LED may preferably have lateral dimensions of less than 80 μm, or 70 μm, or 60 μm, or 50 μm or 30 μm, or 25 μm, or 20 μm, or 15 μm or 10 μm, or 5 μm or 3 μm or 2 μm.

In preferred embodiments, the micro-LED may be square or circular or square with circular corners and have dimensions such as 75 μm×75 μm, 50 μm×50 μm, 40 μm×40 μm, 30 μm×30 μm, 25 μm×25 μm, 20 μm×20 μm or 10 μm×10 μm, or 5 μm×5 um, or 2 μm×2 μm, or 1 μm×1 μm, or 500 n×500 nm or smaller.

The light-emitting region, and/or the LED, may alternatively have lateral dimensions (width and length) of less than 1 μm. In this case, the LED may be termed a “nano-LED”. The nano-LED may preferably have lateral dimensions of less than or 500 nm, or 200 nm, or 100 nm, or 50 nm.

The LEDs may be circular, triangle, rectangular, square, oval, diamond, hexagonal, pentagonal, and any combination of these shapes. In the case of irregular-shapes of pixel design, at least one dimension should fall within the dimensions defined above in order for the LEDs to be classed as mini-or micro-LEDs. For example the width or diameter of the LEDs are preferably less than 100 μm so that the LEDs are classed as micro-LEDs.

Some or all of the device mesas may be a single-emission-wavelength LED structure, which emit at single peak emission wavelengths in response to a driving current.

In a particularly preferred embodiment, the each device mesa is an variable-wavelength LED. Each variable-wavelength LED in the device is preferably independently controllable. Alternatively the device may comprise a plurality of groups of variable-wavelength LEDs, with each group being controllable independently of the other groups.

The device may comprise a plurality of device mesas having a plurality of lateral sizes. For example the device may comprise a first variable-wavelength LED device mesa having a first lateral area, and a second variable-wavelength LED device mesa having a second lateral area different from the first lateral area. The first and second mesas may be first and second variable-wavelength LED subpixels, with the pair of first and second device mesas forming a display pixel. Optionally the device may additionally comprise a third variable-wavelength LED device mesa having a third lateral area different from the first and second lateral areas, the first, second and third variable-wavelength LED device mesas forming three variable-wavelength LED subpixels which together provide a display pixel.

In each device mesa, the device mesa is contacted by a respective metal via which extends through an opening in the liner layer, or alternatively by a metal contact which extends through the opening in the liner layer, the metal contact being electrically connected to the metal via. The size of the opening in the liner dielectric layer defines a contact area across which the device mesa is electrically contacted.

In use, the driving current provided to the device mesa by the driver circuit will have to pass through this contact area to reach the device mesa. Forcing a given magnitude of driving current to flow through a small contact area will create a high current density in the region of the device mesa near the contact area, while applying the same magnitude of driving current through a larger contact area will allow the driving current to spread over the larger contact area so that the device mesa experiences a lower current density. The size of the contact area and the magnitude of the driving current thus determine the driving current density experienced by the device mesa in use.

In a particularly preferred embodiment of the invention discussed further below, the device mesas are variable-wavelength LEDs which respond to different driving current densities by emitting different peak emission wavelengths. Controlling the contact areas on the device mesas may thus advantageously provide an additional way of controlling the driving current densities provided to the variable-wavelength LEDs, and as a result controlling the peak emission wavelength of those LEDs.

The sizes of the contact areas may vary between device mesas. For example a first device mesa may have a first contact area which is in electrical contact with a first metal via. A second device mesa may have a second contact area which is in contact with a second metal via. The size of the second contact area may be different from the size of the first contact area. By providing contact areas having different sizes on different device mesas, it is possible to control the driving current densities which will be experienced by those device mesas. If the contact areas have different sizes, the first and second device mesas will experience a different driving current density when the same magnitude of driving current is provided to both device mesas by the driving circuit.

The device may comprise a plurality of display pixels, each display pixel comprising one or more device mesas. For example a single variable-wavelength LED device mesa may form a display pixel which can emit at different peak wavelengths by varying the driving current provided to that device mesa by the driver circuit. In another embodiment, a pair of first and second variable-wavelength LED device mesas may be two subpixels which combine to create a device pixel, each of the two subpixels being controllable independently of the other by the driver circuit to emit a tuneable peak wavelength which is tuned by varying the driving current provided to the subpixel by the driver circuit. In another embodiment, three device mesas-first, second and third variable-wavelength LED device mesas-may act as three subpixels which combine to create a device pixel, each of the three subpixels being independently controllable by the driver circuit to emit a peak wavelength which is tuned by the driving current provided to the subpixel by the driver circuit.

The driver circuit may be configured to control the power or the current or the voltage of the power supply to each variable-wavelength LED device mesa. The driver circuit may be configured to provide a pulsed, or CW, or quasi-CW power supply to the variable-wavelength LED device mesas.

### Variable-Wavelength LEDS

In a particularly preferred embodiment, each device mesa has the same the variable-wavelength LED device epitaxial structure, such that each device mesa in the device is a separate variable-wavelength LED which is configured to emit a variable peak emission wavelength in response to variations in the driving current provided to that LED. By driving the variable-wavelength LED device mesas separately through the driver circuit it is thus advantageously possible to tune the emission wavelength of each device mesa by providing different driving currents to the variable-wavelength LED device mesas.

Preferably some or all of the device mesas are variable-wavelength LEDs configured to emit a variable peak emission wavelength in response to variations in the driving current provided to the LED, in which the peak emission wavelength of the LED is continuously controllable over an emission wavelength range of at least 40 nm by varying the driving current to the LED. The peak emission wavelength may preferably be variable over an emission wavelength range of at least 50 nm, or at least 60 nm, or at least 70 nm, or at least 80 nm by varying the driving current, preferably over a range of up to 100 nm or 110 nm or 120 nm or 140 nm, or 160 nm, or 180 nm, or 200 nm, or 400 nm, or 450 nm.

The driver circuit is preferably configured to supply a variable-magnitude driving current to the variable-wavelength LED device mesas, to vary the peak emission wavelength of the variable-wavelength LED device mesas.

A variable-wavelength light emitting diode (LED) preferably comprises:
an N-doped Portion;
a p-doped portion;
a light-emitting region located between the n-doped portion and a p-doped portion, the light-emitting region comprising a light-emitting layer which emits light at a peak emission wavelength under electrical bias thereacross;
wherein the LED is configured to receive a power supply, in which the peak emission wavelength of the LED is continuously controllable over an emission wavelength range by varying, or controlling, the power supply. The peak emission wavelength of the variable-wavelength LED is preferably continuously controllable, or continuously variable, over an emission wavelength range of at least 40 nm by varying, or controlling, the power supply.

As the peak emission wavelength of the variable-wavelength LED is preferably continuously controllable, or continuously variable, over an emission wavelength range the LED can be described as a variable-wavelength LED.

The variable-wavelength emission behaviour of the LED structure is enabled by the fact that the LED structure (the n-doped portion, the light-emitting region and the p-doped portion) are grown over a template containing a porous region. The present inventors have found that the presence of a porous region of III-nitride material in the template structure prior to overgrowth of the LED structure leads to higher quality crystal growth and thus significant benefits including the possibility of varying the emission wavelength of the LED light-emitting region. The mechanism by which the porous region enables the variable wavelength emission of the LED is the subject of ongoing study. Benefits provided to the LED by the porous region include strain relaxation, lattice parameter enlargement, wafer bow reduction, and mechanical and thermal influence during the light-emitting region being grown at high temperatures.

The variable-wavelength LED is configured to receive a supply of power, or a drive current, from a power supply or LED driver. The term “power supply” is used herein to refer to the power, or current, supplied to drive an LED during use.

The peak emission wavelength of the LED may preferably be continuously controllable, or continuously variable, over an emission wavelength range by varying, or controlling, the magnitude of a drive current provided to the variable-wavelength LED.

In traditional LED devices, changes to the driving current provided to the LED produces a very small shift in emission wavelengths, but the present inventors have found that the wavelength shift can be broadened and controlled to a greater extent than traditional LED materials. Rather than the few nm emission range of prior art devices, the LED of the present invention is controllable to emit over a far broader emission range, for example a range of at least 40 nm. As the present LED is tunable to emit over a broad wavelength range, it may be referred to as a variable-wavelength LED.

The LED may be a dynamic colour-tunable LED, in which the peak emission wavelength of the LED is tunable by varying the driving conditions provided to the LED by the power supply.

The LED is preferably driveable to emit at a single peak emission wavelength in response to a stable power supply, but to emit at different peak emission wavelengths in response to variations in the power supply. Thus the LED may be used to emit a particular colour for a prolonged period, or alternatively the LED may be driven to emit a variety of different wavelengths by providing varying driving conditions.

Preferably, the n-doped portion, the p-doped portion and the light-emitting region all comprise or consist of III-nitride material, preferably GaN, InGaN, AlGaN or AlInGaN

The variable-wavelength LED preferably contains a single epitaxially-grown diode structure containing the n-doped portion, the p-doped portion and the light-emitting region. Thus the variable peak emission wavelengths of the LED are all emitted by the same LED diode structure and composition.

The LED preferably comprises a porous region of III-nitride material. The light-emitting region of the LED is preferably formed over a porous region of III-nitride material. In some embodiments, one of the n-doped portion or the p-doped portion may contain the porous region of III-nitride material. In other embodiments, the n-doped portion; the p-doped portion; and the light-emitting region are provided on a substrate which comprises the porous region of III-nitride material. During epitaxial growth of the LED, the light-emitting region is preferably overgrown after the porous region has been formed.

The present inventors have found that a porous region of III-nitride material enables the same LED to emit at a range of peak emission wavelengths, rather than at one specific wavelength. The peak emission wavelength of the LED may be varied across an emission wavelength range by varying the power supply provided to the LED. The present invention therefore provides a variable-wavelength LED, which may be controlled to emit at any wavelength across a continuous emission wavelength range. By varying the driving conditions provided to the LED by the power supply, the LED is capable of emitting at any wavelength within the emission wavelength range of said LED, and not simply at discrete peak emission wavelengths.

The present inventors have found that the ability of the LED to emit at tuneable wavelengths across a broad emission range may be imparted by either incorporating a porous region of III-nitride semiconductor material into the LED structure, or forming the LED diode structure over a porous region of III-nitride semiconductor material. Benefits provided to the LED by the porous region include strain relaxation, lattice parameter enlargement, wafer bow reduction, and beneficial mechanical and thermal influences during the growth of the light-emitting region at high temperatures.

The light-emitting region of the LED is preferably formed over a porous region of III-nitride material during manufacture, so that the porous region influences the structure and mechanical properties of layers of semiconductor that are epitaxially deposited over the porous region. Layers of semiconductor material that are deposited over the porous region during growth experience benefits such as strain reduction, lattice parameter enlargement, and wafer bow reduction, which are imparted to the LED light-emitting region and affect its structure and its light-emitting behaviour.

Once the LED light-emitting (active) region has been epitaxially grown over the porous region, and the quality of the active region has been enhanced by the influence of the porous region, the beneficial effects of the porous region on the emission properties are permanently imparted to the LED active region. Thus the LED diode structure may be retained on the porous region, in which case the variable-wavelength LED comprises a porous region of III-nitride material, or alternatively, during the processing of LEDs into devices after epitaxial growth, the porous region may be removed from the LED structure. The width of the emission wavelength range may vary depending on the structure and composition of the LED structure (the n-doped portion, light-emitting region and p-doped portion), and on the structure and porosity of the porous region. The width of the emission wavelength range may also vary depending on the size and shape of the LED (the pixel size and shape).

In preferred embodiments, the peak emission wavelength is controllable over an emission wavelength range of at least 40 nm, or at least 50 nm, or at least 60 nm, or at least 70 nm, or at least 80 nm by varying the power supply. Preferably the peak emission wavelength is controllable over an emission wavelength range of up to 100 nm, or 110 nm, or 120 nm, or 130 nm, or 140 nm, or 150 nm, or 160 nm, or 170 nm, or 180 nm, or 190 nm, or 200 nm, or 400 nm, or 450 nm. The size of the emission wavelength range obtainable by the present LED is thus far greater than the emission ranges achievable with LEDs of the prior art.

The variable-wavelength LED is advantageously controllable to emit at any peak emission wavelength within its emission wavelength range. By varying the characteristics of the power supply and LED pixel size and shape, the variable-wavelength LED may therefore be controlled to emit light at any selected peak emission wavelength within this range.

The emission wavelength of the variable-wavelength LED is preferably continuously variable across its emission wavelength range in response to driving conditions provided by a power source being varied continuously across a range of driving conditions.

The position of the emission wavelength range in the electromagnetic spectrum may also vary depending on the design of the variable-wavelength LED structure (the n-doped portion, light-emitting region and p-doped portion). For example the wavelengths contained in the emission wavelength range may depend on the number and composition of light emitting layers in the variable-wavelength LED. A large variety of LED active regions are known in the art for emitting at different wavelengths in the visible spectrum, so by light-emitting region forming the LEDs of the present invention with different light-emitting regions, emission wavelength ranges covering different portions of the spectrum may be obtained.

The variable-wavelength LED emission wavelength range may be between 400 nm and 850 nm, or between 400 nm and 800 nm, or between 400 nm and 690 nm, or between 400 nm and 675 nm. The emission wavelength range may be a sub-range within the range of 400 nm to 750 nm. The emission wavelength range may be tuned to cover any part of this range by selecting different LED active regions and controlling the size and shape of the LED pixels.

Preferably the emission wavelength range of the variable-wavelength LED extends from a lower end below 410 nm, or 430 nm, or 450 nm, or 470 nm, or 500 nm, or 520 nm, or 540 nm, or 560 nm, to an upper end above 570 nm, or 580 nm, or 600 nm, or 610 nm, or 630 nm, or 650 nm, or 675 nm. The first and second ends of the emission wavelength range may be tuned depending on the selection of LED structure and LED shape and size, as described above.

For example in preferred embodiments the lower end of the emission wavelength may be between 400 nm and 450 nm (violet) or between 450 nm and 500 nm (blue) or between 500 nm and 570 nm (green), and the upper end of the emission wavelength may be between 570 nm and 590 nm (yellow), or between 590 nm and 610 nm (orange), or between 610 and 700 nm (red).

In a preferred embodiment, the variable-wavelength LED emission wavelength range may extend from a lower end that is below 500 nm to a higher end that is above 610 nm, so that the peak emission wavelength of the LED may be varied to emit at any wavelength from blue (below 500 nm) to red (above 610 nm) by varying the power supply. Providing a single LED design that can be controlled to emit at blue wavelengths (450-500 nm), green (500-570 nm) and also at yellow (570-590 nm), orange (590-610 nm) and red (610-760 nm) is highly advantageous, and could provide significant advantages for LED displays.

In other preferred embodiments, the variable-wavelength LED emission wavelength range may extend between 520 nm and 660 nm, or between 550 nm and 650 nm, by varying the power supply to the LED.

In a particularly preferred embodiment, the peak emission wavelength is controllable between 540 nm and 680 nm, or between 560 nm and 675 nm, by varying the power supply. Thus, the same LED may be controllable to emit at a peak emission wavelength anywhere between 540 nm in the green and 680 nm in the red. Green and red LEDs have historically been more difficult to manufacture than shorter wavelength blue LEDs due to issues such as the difficulty of incorporating the required indium content into the light-emitting region. Providing a single LED design that can be controlled to emit at green wavelengths (500-570 nm) and also at yellow (570-590 nm), orange (590-610 nm) and red (610-760 nm) is therefore highly advantageous, and could provide significant advantages for LED displays.

In another preferred embodiment, the peak emission wavelength is controllable between 520 nm and 675 nm, or between 550 nm and 650 nm, by varying the power supply.

Although the variable-wavelength LED can emit across a continuous emission wavelength range, in some embodiments it may be desirable to control the LED to function in a plurality of discrete emission modes, for example in response to a power supply having a plurality of driving modes. For example by driving the LED in a plurality of different modes corresponding to discrete emission colours, a simplified colour display may be provided, in which discrete emission colours are mixed in known methods to give a desired visual effect.

The variable-wavelength LED is preferably controllable to emit at least two discrete peak emission wavelengths by varying the driving conditions provided by the power supply between two discrete driving conditions (such as two discrete magnitudes of drive current). The LED may be controllable to emit at a first peak emission wavelength in response to a first driving condition provided by the power supply (which may be a drive current having a first magnitude), at a second peak emission wavelength in response to a second driving condition provided by the power supply (which may be a drive current having a second magnitude different from the first magnitude).

The variable-wavelength LED is preferably controllable to emit at least three discrete peak emission wavelengths by varying the driving conditions provided by the power supply. The peak emission wavelength of the variable-wavelength LED may thus be variable over at least three “colours” in the EM spectrum.

The variable-wavelength LED may be controllable to emit at a first peak emission wavelength in response to a first driving condition provided by the power supply, at a second peak emission wavelength in response to a second driving condition provided by the power supply, and at a third peak emission wavelength in response to a third driving condition provided by the power supply.

The variable-wavelength LED may preferably be controllable to emit a blue peak emission wavelength in response to a first driving condition provided by the power supply, to emit a green peak emission wavelength in response to a second driving condition provided by the power supply, and to emit a red peak emission wavelength in response to a third driving condition provided by the power supply.

The variable-wavelength LED may be controllable to emit a first peak emission wavelength in the range 400-500 nm in response to a first driving condition provided by the power supply, to emit a second peak emission wavelength in the range 500-550 nm in response to a second driving condition provided by the power supply, and to emit a third peak emission wavelength greater than 600 nm in response to a third driving condition provided by the power supply.

Preferably, the variable-wavelength LED is controllable to emit a first peak emission wavelength in the range 430-460 nm in response to a first driving condition provided by the power supply, to emit a second peak emission wavelength in the range 510-560 nm in response to a second driving condition provided by the power supply, and to emit a third peak emission wavelength in the range 600-660 nm in response to a third driving condition provided by the power supply.

The first, second and third driving conditions may be first, second and third current densities, or the first, second and third driving conditions may be first, second and third power densities.

The morphology of quantum wells (QWs) in the active light-emitting region may be varied. For example the light-emitting region may contain uniform QWs with well-defined interfaces or fragmented QWs with less well-defined interfaces, fragmentation, or QW well width/composition fluctuation or quantum dots like localisation centres. This control of QW morphology can determine the range of the variable emission wavelength to be controlled and manipulated.

The light-emitting region preferably comprises a plurality of quantum wells (QWs). The quantum wells may be continuous. The quantum wells may be fragmented, or discontinuous.

The variable-wavelength LED may comprise a current constraining layer, or a current limiting layer, which is a dielectric layer configured to confine the lateral area of the LED through which current is conducted. The use of a current constraining layer may advantageously allow further control of the current density, in order to better control the peak emission wavelength of the LED.

The current constraining layer may advantageously enable the manipulation of the power density provided to the variable-wavelength LED, in order to control the peak emission wavelength.

The current constraining layer is preferably a layer of dielectric material. For example, the current constraining layer may be any dielectric, for example SiO₂, SiN or SiNx.

The current constraining layer may be positioned in a variety of positions in the variable-wavelength LED, as long as it confines the lateral area of the LED through which current is conducted. The current constraining layer may be positioned in the LED between an electrical n-contact and an electrical p-contact.

The current constraining layer may be positioned adjacent to either the n-doped portion or the p-doped portion of the LED. For example the current constraining layer may be positioned between the n-doped portion and the light-emitting region. Alternatively the current constraining layer may be positioned between the light-emitting region and the p-doped portion. The current constraining layer may be positioned between an electrical contact and the LED structure (n-doped portion, p-doped portion and light-emitting region).

The current constraining layer preferably comprises an aperture extending through the current constraining layer, or one or more apertures extending through the current constraining layer. The aperture may preferably be positioned in the centre of the current constraining layer. For example the current constraining layer may comprise a circular opening in the centre of the LED structure.

The variable-wavelength LED may be configured so that an electrical contact is in contact with the LED structure via the aperture in the current constraining layer, so that the area of the aperture defines a contact area over which the contact and the LED structure are touching.

The lateral dimensions of the or each aperture is preferably much smaller than the lateral dimensions of the LED. By providing an aperture through the dielectric current constraining layer, high local current density may be achieved, which may advantageously enable improved control of the power through the LED.

For example the lateral width (or diameter) of the aperture may be equal to or less than 50% of the lateral width of the LED structure (the LED mesa). The width of the aperture may be equal to or less than 45%, or 40%, or 35%, or 30%, or 25%, or 20% of the width of the LED structure.

The relative area of the aperture compared to the overall area of the current constraining layer (the blocked region) may be varied to modify the local current density.

The light emitting region preferably comprises a multiple quantum well (MQW) containing a plurality of quantum wells (QWs), or quantum dots, quantum wires, or other quantum nanostructures.

In some embodiments, the light-emitting region comprises a plurality of quantum wells (QWs), and the quantum wells are continuous.

The present inventors have found that non-uniformities in the light-emitting region have a significant effect in broadening the emission wavelength range across which a light-emitting region can emit light in response to variations in the power supplied to the LED. In the prior art, non-uniformities in the light-emitting region are typically considered problematic flaws, which are unwanted and should be avoided in any way possible because the goal is typically a high-quality, low-flaw semiconductor wafer. The present inventors have eschewed this prejudice in the art, and found that intentionally creating non-uniformities in the light emitting region may advantageously broaden the emission wavelength range and result in a variable-wavelength LED which can emit over a far broader wavelength range than has ever been possible in the prior art.

In alternative embodiments of the present invention, the light-emitting region is non-uniform, fragmented, or discontinuous. The light-emitting region may be deliberately introduced to achieve the effect of carrier localisation centres in InGaN quantum wells, such as multiple types of QW region with different Indium composition and well width and quantum barriers, non-uniform, or fragmented, or broken, or gappy, or discontinuous quantum wells which would result in fluctuation in the well width, InGaN quantum dots or nanostructures, quantum wells formed on polar, semi-polar or non-polar facets.

In a preferred embodiment, the light-emitting region comprises a plurality of quantum wells (QWs), and the quantum wells are non-uniform, fragmented, or discontinuous.

The plurality of QWs may comprise fluctuations in well-width. For example the well width of the QWs may fluctuate by at least 2%, 5%, 10%, 20%, 25%, or 50%, or 75%. The well width fluctuations can be variations between quantum wells (vertical direction) as well as within one quantum well (lateral direction).

The plurality of QWs may comprise fluctuations in alloy composition. For example the indium composition of the QWs may vary by at least 2%, 5%, 10%, 20%, 25% or 50% or 75% across the light-emitting region.

The inventors have found that fluctuations in well-width and/or alloy composition may induce carrier localisation centres, either in the upper interface or lower interface of the QWs. Any carrier localisation centres would induce the variable wavelength in the variable-wavelength LED of the present invention. The larger the density of those carrier localisation centres, the larger the variable wavelength range can be achieved.

The variable-wavelength LED may comprise a v-shaped pit which extends, or propagates, through the light emitting active region. Preferably the LED comprises a plurality of v-shaped pits which extend through the light-emitting region.

Preferably the variable-wavelength LED may comprise a density of v-shaped pits (measured looking down onto the LED structure from above) of at least 1×10⁷/m², for example at least 5×10⁷/cm² or at least 1×10⁸/cm², for example a density of v-shaped pits of 1×10⁷/cm² to 5×10⁹/cm².

The variable-wavelength LED may comprise a density of v-shaped pits of less than 5×10⁹/cm², for example a density of v-shaped pits of less than 1×10⁹/cm² or less than 5×10⁸/cm².

V-shaped pits are a phenomenon known in the art of epitaxial semiconductor growth, and methods of growing v-shaped pits in semiconductor structures are known in the art. For example, v-shaped pits and their growth are described in the prior art in The effect of nanometre-scale V-pits on electronic and optical properties and efficiency droop of GaN-based green light-emitting Diodes; Zhou et al; Scientific Reports|(2018) 8:11053|DOI:10.1038/s41598-018-29440-4.

These v-shaped pits are v-shaped when viewed in cross-section, but in reality form as conical or funnel-shaped voids in semiconductor structures that are grown from the bottom up using conventional epitaxial growth methods. While the cross-section of the pits is v-shaped, the pits are typically hexagonal when viewed from above. The point of the v-shaped pits are always directed downwards towards earlier-deposited layers of semiconductor structure, as the pits widen as subsequent layers of epitaxial growth are deposited on top of the structure.

Although v-shaped pits are known in the art, they are typically considered a problematic flaw in semiconductor structures, which are unwanted because the goal is typically a high-quality, low-flaw semiconductor wafer.

In the unusual situations where v-shaped pits have been incorporated into semiconductor structures in the past, the v-shaped pits have been used as a screening mechanism to create higher band gap regions which prevent current carriers going down threading dislocations as a leakage path.

In some preferred embodiments of the present invention, however, v-shaped pits are intentionally incorporated into the variable-wavelength LED structure. The v-shaped pits extend far enough down into the semiconductor structure that they terminate in a layer below the active light-emitting region. This means that the v-shaped pits must extend through the thickness of the active light-emitting region.

The present inventors have found that v-shaped pits extending through the light-emitting region of the LED structure may advantageously broaden the emission wavelength range over which a variable-wavelength LED can emit.

As the v-shaped pits extend through the active region of the LED, during epitaxial growth from the bottom up, quantum well (QW) layers that are planar across the rest of the structure are grown on the sloping side walls of the v-shaped pits. The QWs deposited on the pit sidewalls are distorted and stretched around the sides of the pits, so end up being of different thickness and composition compared to the planar QWs across the bulk of the structure.

Around the v-shaped pits, QW layers of semiconductor material are grown as flat planar layers. The active light-emitting region is thus planar around the v-shaped pit. In the location of the v-shaped pits, however, the active layers are distorted and stretched downwards along the sidewalls into the v-shaped pit. This stretching effect changes the thickness of the QWs on the sidewalls of the pit, so that they are different in thickness compared to the planar QW layers formed over the rest of the LED structure.

The inventors have found that v-shaped pits can create local strain relaxation, and MQWs deposited on the sidewall of these v-pits will have different thickness and composition compared to the rest of the MQW, hence the MQW in the region of the v-shaped pits will produce a different emission wavelength.

The quantum wells grown on the side walls of the v-shaped pit are thinner than the bulk planar QWs elsewhere in the structure, which may affect the QW bandgap and allow the QWs in this region to emit at wavelengths different from those emitted by the planar QWs elsewhere in the structure. In addition to this, the QWs on the pit sidewalls may end up having a higher indium (In) content than the surrounding planar QWs, because the sidewalls expose a semipolar facet of the QWs—this facet incorporates more indium during epitaxial growth, so the QWs in the region of the v-shaped pits may be higher in indium than the planar QWs around the pits. Higher indium incorporation typically leads to longer peak emission wavelengths. Both the QW thickness and the indium content affect the emission wavelengths produced by the light-emitting region. The presence of v-shaped pits in the LED structure may thus advantageously modify the composition and thickness of QWs in the light-emitting region in a way that expands the emission wavelength range over which the LED can be driven to emit light.

V-shaped pits typically grow from threading dislocations in the semiconductor structure.

The threading dislocations are perpetuated upwards through the structure as additional layers are grown over layers containing a threading dislocation, and at a certain point the dislocation widens into a v-shaped pit. Typically the skilled person aims to keep threading dislocation concentrations low in order to produce a “high quality” low-flaw wafer.

V-shaped pits can alternatively be grown using 3-dimensional epitaxial growth modes. 3D epitaxial deposition techniques are known in the art and are typically used to grow “islands” or “pyramids” of semiconductor material on a template. By controlling deposition of the LED structure using 3D epitaxial deposition techniques, v-shaped pits can be artificially grown in desired locations, with no need for a threading dislocation to be present to “seed” the formation of the v-shaped pit. By using this deposition control, the bottom (nadir) of the pit may be created at a desired location in the structure-both a desired lateral position and a desired height in the structure, for example in a particular layer of the semiconductor structure below the active light-emitting region.

The bottom of the v-shaped pit may be located in the connecting layer of the semiconductor structure. The connecting layer may be positioned between the porous region and the n-doped portion.

The bottom of the v-shaped pit may be located in a pre-strain layer of the semiconductor structure. The pre-strain layer may be positioned above the n-doped portion and below the light-emitting region.

Preferably the variable-wavelength LED comprises a plurality of v-shaped pits which extend through the active light-emitting region.

Preferably the variable-wavelength LED comprises a density of v-shaped pits (measured looking down onto the LED structure from above) of at least 1×10⁷/cm², for example at least 5×10⁷/cm² or at least 1×10⁸/cm². The LED may comprise a density of v-shaped pits of less than 5×10⁹/cm², for example a density of v-shaped pits of less than 1×10⁹/cm² or less than 5×10⁸/cm².

For example the variable-wavelength LED may comprise a density of v-shaped pits of 1×10⁷/cm² to 5×10⁹/cm², or 5×10⁷/cm² to 5×10⁹/cm², or 1×10⁸/cm² to 5×10⁸/cm².

The variable-wavelength LED may comprise more than 0.1 v-shaped pit per square micrometre, or more than 1 v-shaped pits per square micrometre, or more than 2 v-shaped pits per square micrometre.

The concentration of v-shaped pits in the variable-wavelength LED is preferably controlled, as too many v-shaped pits may negatively affect the light emission of the LED by disrupting radiative recombination. For example the LED may comprise fewer than 10 v-shaped pits per square micrometre, or fewer than 8 v-shaped pits per square micrometre, or fewer than 6 v-shaped pits per square micrometre.

In a preferred embodiment the LED structure may comprise no greater than 10\hat{ }9 threading dislocations per square centimetre. Preferably the semiconductor structure below the active light-emitting region (typically a substrate, the porous region and a connecting layer) comprise no more than 10\hat{ }9 threading dislocations per square centimetre. The threading dislocation density is preferably limited to this level so that further epitaxial growth does not create too many v-shaped pits in the light-emitting region.

Both the density and size (the depth) of the v-shaped pits may be controlled. The size of the V-pits can be controlled by the position and the growth conditions of the pre-strain layer and the low-temperature nGaN layer where the pits started.

The morphology of quantum wells (QWs) in the active light-emitting region may be varied. For example the light-emitting region may contain uniform QWs with well-defined interfaces or fragmented QWs with less well-defined interfaces, fragmentation, or QW well width/composition fluctuation or quantum dot like localisation centres. This control of QW morphology can determine the range of the variable emission wavelength to be controlled and manipulated.

The light-emitting region preferably comprises a plurality of quantum wells (QWs). The quantum wells may be continuous. The quantum wells may be fragmented, or discontinuous.

If QWs are continuous and very uniform in thickness and composition, recombination of charge carriers can only happen in regular well defined ways. On the other hand, if QWs are fragmented or discontinuous, this creates lots of nanostructures, which in turn creates different band gaps that result in emission of different colours.

### BRIEF DESCRIPTION OF THE DRAWINGS

Embodiments of the invention will now be described with reference to the figures, in which:

FIGS. 1A-1D are a step-by-step illustration of a “wafer bond” prior art method for integrating RGB subpixels into a display device;

FIGS. 2A-2D are a step-by-step illustration of a “mass transfer” prior art method for integrating RGB subpixels into a display device;

FIGS. 3A-3I are a step-by-step illustration of a method manufacturing an opto-electronic device according to an embodiment of the present invention;

FIGS. 4A-4J are a step-by-step illustration of a method manufacturing an opto-electronic device according to an alternative embodiment of the present invention;

FIG. 5 is a schematic illustration of a porous region of III-nitride material configured as a DBR for light extraction improvement in an optoelectronic device, according to a preferred embodiment of the present invention;

FIG. 6 is a schematic illustration of a porous region of III-nitride material configured as an anti-reflection layer for light extraction improvement in an optoelectronic device, according to a preferred embodiment of the present invention;

FIG. 7 is a schematic illustration of a porous region of III-nitride material configured as a colour filter for light extraction improvement in an optoelectronic device, according to a preferred embodiment of the present invention;

FIG. 8 is a schematic illustration of an optoelectronic device containing a porous III-nitride region on either side of the device structure acting as DBR/AF pairs, according to a preferred embodiment of the present invention;

FIGS. 9A and 9B are schematic illustrations of a multi-layered porous region of III-nitride material being etched into a multi-zone optical filter/AF layer;

FIG. 10 is a series of five EL images of the same MicroLED pixel being driven at different currents in constant wave mode (CW), showing five different colours of emission;

FIG. 11A is an emission wavelength vs current density plot for a 25 μm×25 μm100×100 variable-wavelength LED pixel array driven in pulsed mode with a 100 μs pulse at 1% duty cycle;

FIG. 11B is an emission wavelength vs current density plot for a 30 μm×30 μm 100×100 variable-wavelength LED pixel array driven in pulsed mode with a 100 μs pulse at 1% duty cycle;

FIG. 12 is a plot of intensity vs wavelength for a single variable-wavelength LED driven at different currents in pulsed driving mode with a 100 82 s pulse at 1% duty cycle;

FIGS. 13A-G illustrate alternative embodiments of non-uniform, fragmented or discontinuous light-emitting regions of variable-wavelength LEDs usable in preferred embodiments of the present invention;

FIG. 14A is a TEM image of a cross-section of a conventional non-variable-wavelength LED;

FIG. 14B is a TEM image of the light-emitting region of a variable-wavelength LED comprising v-shaped pits, usable in embodiments of the present invention;

FIG. 14C is a TEM image of the variable-wavelength LED of FIG. 14B, showing a porous region and a light-emitting region comprising a plurality of v-shaped pits, usable in a preferred embodiment of the present invention;

FIG. 15A is a graph of peak emission wavelength vs driving current density for a conventional non-variable wavelength LED;

FIG. 15B is a graph of peak emission wavelength vs driving current density for a variable-wavelength LED according to an embodiment of the present invention;

FIG. 15C is a graph of peak emission wavelength vs driving current density for a variable-wavelength LED according to another embodiment of the present invention;

FIG. 16A is a graph of peak emission wavelength vs driving current density for another variable-wavelength LED usable in embodiments of the present invention;

FIGS. 16B-D are photographs of the variable-wavelength LED of FIG. 16A, with inset emission spectra showing the different peak emission wavelengths at different driving current densities.

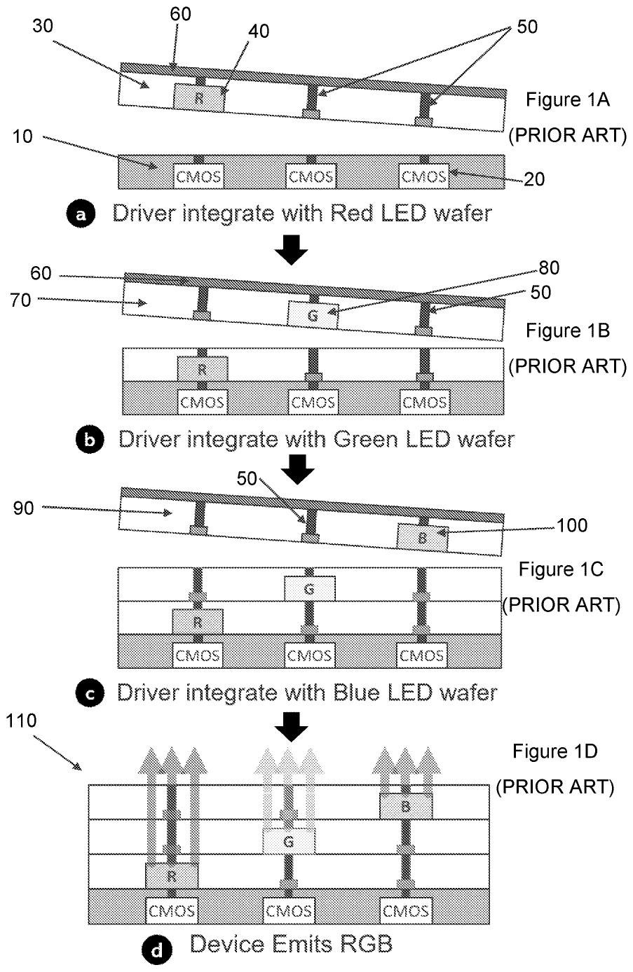

FIGS. 1A-1D are a step-by-step illustration of a “wafer bond” prior art method for integrating RGB subpixels into a display device.

In FIG. 1A, a driver wafer 10 comprising three CMOS LED drivers 20 is integrated with a red (R) LED device wafer 30 comprising a red LED 40 in an epitaxial structure formed over a growth substrate wafer 60. The red LED device wafer 30 is bonded to the driver wafer 10 in a flip-chip fashion using conventional wafer bonding techniques. The Red LED wafer 30 contains one red LED 40, which is aligned to be electrically connected to one of the three CMOS LED drivers 20 when the Red LED wafer is bonded to the driver wafer. Conductive vias 50 which extend through the device wafer are aligned with the other two CMOS drivers 20. The growth substrate wafer 60 is removed from the red LED device wafer 30 to expose the device wafer's upper surface after it has been bonded to the driver wafer 10.

In FIG. 1B, a green (G) LED device wafer 70 is bonded to the upper surface of the red LED device wafer 30 in a flip-chip fashion using conventional wafer bonding techniques.

The green LED wafer 70 comprises a green LED 80 in an epitaxial structure formed over a growth substrate wafer 60. The green LED 80 is aligned to be electrically connected to one of the two CMOS LED drivers 20 not connected to the red LED. Conductive vias 50 which extend through the green LED device wafer 70 are aligned with the red LED 40 and the remaining CMOS driver. The growth substrate wafer 60 is removed from the green LED device wafer 70 after it has been bonded to the red LED device wafer 30.

In FIG. 1C, a blue (B) LED device wafer 90 is bonded to the upper surface of the green LED device wafer 70 in a flip-chip fashion using conventional wafer bonding techniques.

The blue LED wafer comprises a blue LED 100 in an epitaxial structure formed over a growth substrate wafer 60. The blue LED 100 is aligned to be electrically connected to the only remaining CMOS LED driver 20 not connected to one of the other LEDs. Conductive vias 50 which extend through the blue LED device wafer 90 are aligned with the red LED 40 and the green LED 80. The growth substrate wafer 60 is removed from the blue LED device wafer 90 after it has been bonded to the green LED device wafer.

FIG. 1D shows the integrated device 110 once the growth substrate wafer 60 has been removed from the blue LED device wafer 90, and after further conventional processes, such as the attachment of electrical contacts (not shown), have taken place. Each of the R, G and B LEDs are electrically connected to their own CMOS LED driver 20, so that each of the LEDs can be separately turned on and off.

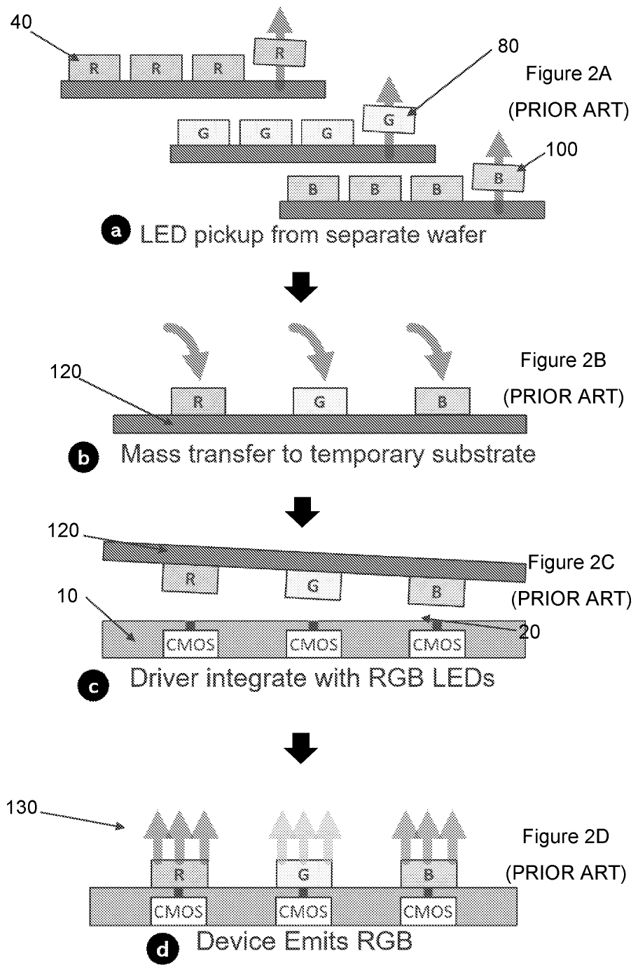

FIGS. 2A-2D are a step-by-step illustration of a “mass transfer” prior art method for integrating RGB subpixels into a display device.

In this “pick-and-place” integration method, red (R), green (G) and blue (B) LEDs 40, 80, 100 are each grown on their own growth substrates 60, before being “picked-up” (removed) from their growth substrates as shown in FIG. 2A. As shown in FIG. 2B, all three separate LEDs are then transferred and bonded onto a shared RGB device wafer 120 which acts as a temporary substrate. As shown in FIG. 2C, the shared RGB device wafer is then bonded to a driver wafer 10 in a flip-chip fashion using conventional wafer bonding techniques. Each of the R, G and B LEDs 40, 80, 100 is aligned with its own CMOS LED driver 20 in a driver circuit of the driver wafer 10, so that each LED is driveable separately from the others. As shown in FIG. 2D, the temporary substrate 60 is removed, leaving a display device 130 the R, G and B LEDs bonded to the driver wafer 10.

As in FIGS. 1A-1D, for simplicity some standard device processing steps are not shown.

### Embodiment 1

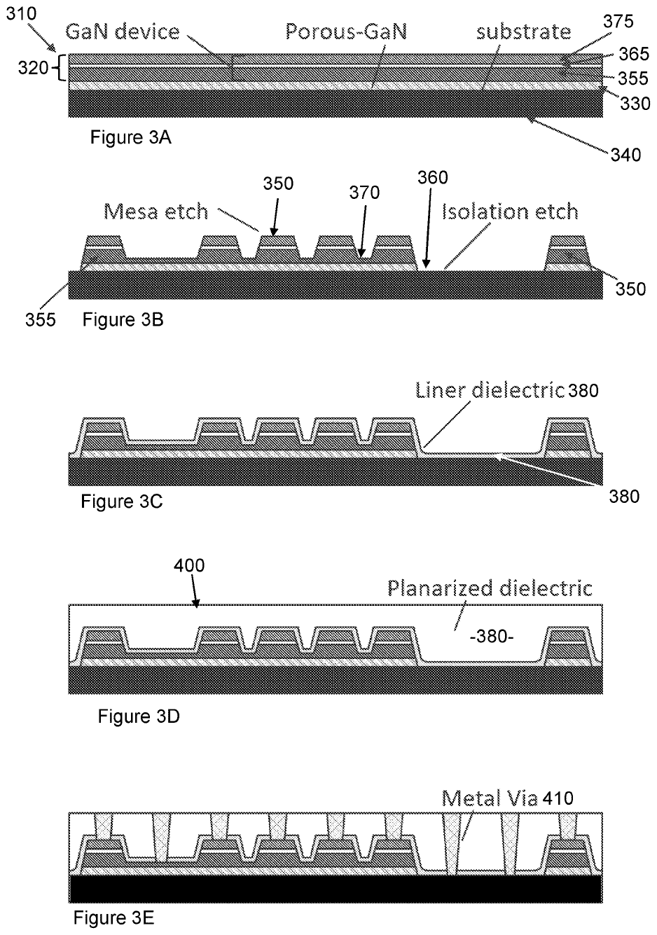

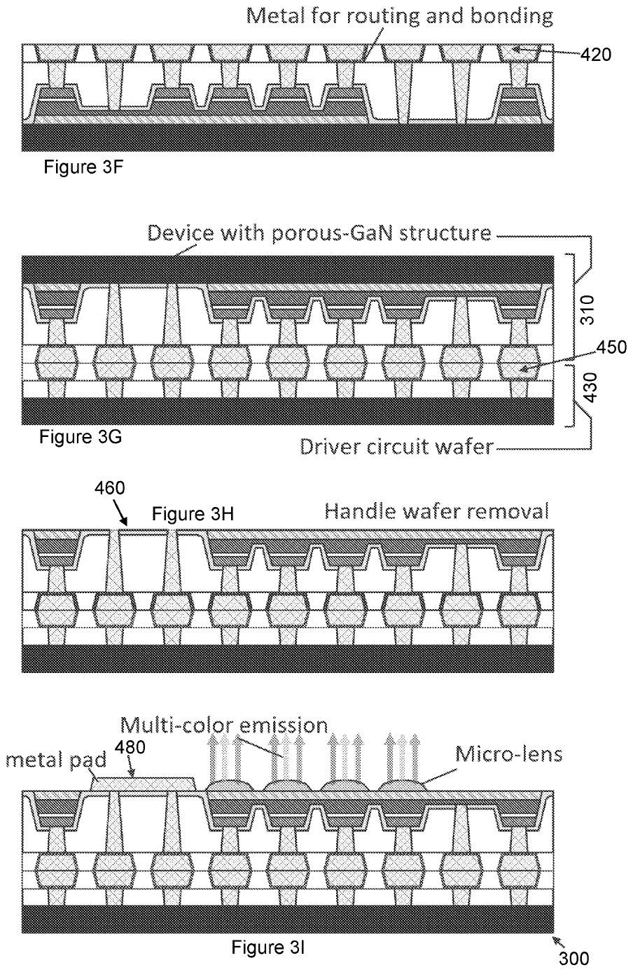

FIGS. 3A-3I are a step-by-step illustration of a method manufacturing an opto-electronic device 300 according to an embodiment of the present invention.

FIG. 3A shows a device wafer 310 consisting of a semiconductor device epitaxial structure 320 formed over a porous layer 330 of III-nitride material on a substrate wafer 340.

Additional layers of semiconductor material may be provided above or below the porous layer, but are omitted from the illustrations for simplicity.

While shown as GaN in the Figures, a variety of III-nitride semiconductor materials may alternative be used. Preferably all of the semiconductor material used in the present invention is III-nitride semiconductor material. Thus preferably the wafer comprises a plurality of layers of III-nitride semiconductor material on the substrate. Each semiconductor layer in the wafer (besides the substrate) is preferably formed from one of GaN, InGaN, AlGaN, AlInGaN or AIN.

The porous layer 330 may take a variety of forms, as discussed further below. For example, depending on the intended application of the device, the porous layer may be a multi-layer porous region comprising a plurality of layers of porous and optionally non-porous III-nitride material.

The porous layer 330 may have been porosified by electrochemical etching as set out in international patent applications PCT/GB2017/052895 (published as WO2019/063957) and PCT/GB2019/050213 (published as WO2019/145728) prior to overgrowth of the device epitaxial structure.

The substrate wafer 340 may be Silicon, Sapphire, SiC, β-Ga2O3. The crystal orientation of the substrates can be polar, semi-polar or non-polar orientation. The substrate thickness may typically vary between 100 μm and 1500 μm. The wafer may have a variety of sizes, such as 1 cm², or 2 inch, 4 inch, 6 inch, 8 inch, 12 inch, or 16 inch diameter or larger.

A variety of device epitaxial structures 320 may be used in the present invention. The device epitaxial structure may be any opto-electronic semiconductor device, for example a VCSEL, but will be described herein by reference to a light emitting diode (LED) structure having an n-type region 355, a light-emitting region 365 and a p-type region 375.

For example the device epitaxial structure 320 may be a conventional LED epitaxy.

The device epitaxial structure 320 may be an LED as described, for example, in international patent applications PCT/GB2021/050152 (published as WO2021/148808) and PCT/GB2021/052020 (published as WO2022/029434).

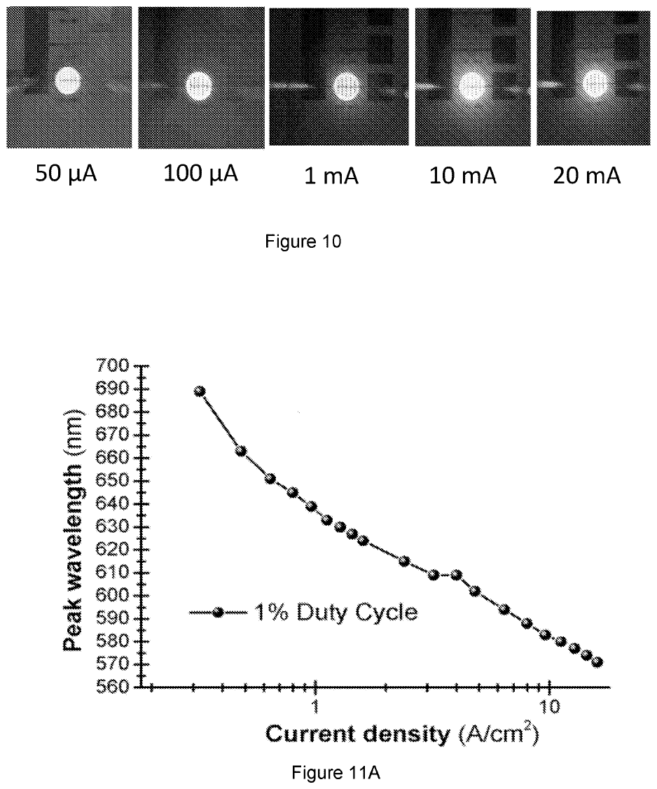

In a particularly preferred embodiment, the device epitaxial structure 320 may be a variable-wavelength LED epitaxial structure as described further above and below with reference to FIGS. 10-16E.

As shown in FIG. 3B, the device wafer 310 is etched into a plurality of discrete device mesas 350 by etching a series of trenches through the device structure, each device mesa 350 being a “tower-like” structure containing an n-type region 355, a light-emitting region and 365 a p-type region 375. As all of the device mesas 350 are etched from the same epitaxial structure 320, the layered structure of each mesa is identical. The lateral dimensions of the device mesas, however, may differ depending on the lateral spacing of the trenches. By controlling the spacing of the trenches, the device mesas may be formed into mini-LEDs, micro-LEDs or nano-LEDs for example.

The device wafer 310 may be etched by conventional etching techniques known to the person skilled in the art. For example the device wafer may be etched using wet chemistry or a sputter etch process using Argon. This step may be followed by wet or dry etching of the III-nitride structure. An inductively coupled plasma reactive ion etching, only reactive ion etching or neutral beam etching may be used to create mesas in the III-nitride layer.

The dry etch process may include either one or more of Cl, Ar, BCl₃, SiCl₄ gases.

After the dry etch process a wet etch process may be carried out to remove dry etching damage from the sidewalls of the mesa. The wet chemistry may involve KOH (1-20%), TMAH or other base chemistries.

As shown in FIG. 3B, trenches may be etched to different depths in the device structure 310.

Isolation etches may be performed, in which an isolation trench 360 is etched all the way through the depth of the semiconductor structure 320, so that the bottom of the trench reaches the substrate wafer 340. These isolation trenches sever all electrical pathways between the device mesas on either side of the isolation trench, so that the mesas on either side of the isolation trench are electrically isolated from one another.

Shallower mesa trenches 370 may be etched into the device wafer 310 without penetrating all the way to the substrate wafer 340. Mesa trenches 370 should be etched to a depth greater than the depth of the LED light-emitting region, so that the light-emitting regions of separate device mesas 350 are separate from one another. Depending on the depth to which the mesa trenches extend into the epitaxial structure, the device mesas on either side of the mesa trench may be electrically connected to one another, for example if an electrically-conductive layer of the device wafer extends intact below the depth of the mesa trench, to allow electrical conduction between device mesas. For example in the illustrated embodiment, the mesa trenches are shown not to be etched all of the way through the n-type layer of the semiconductor device structure, so that the n-type layer will electrically connect all of the mesas which are still epitaxially connected to the same portion of n-type layer.

The positions of the device mesas 350 may be varied and controlled by selecting the positions and sizes of the trenches etched into the wafer.

After the device wafer has been etched into a plurality of device mesas, a liner dielectric layer 380 is deposited over the wafer and the device mesas, as shown in FIG. 3C. The liner dielectric layer may be formed from, for example, silicon dioxide or silicon nitride dielectric.

As shown in FIG. 3D, a dielectric filler material 390 is deposited over the device wafer. The dielectric filler material fills the mesa trenches 370 and isolation trenches 360 and is planarized to provide a flat, or planar, upper surface 400 on the device wafer.

Metal vias 410 are then formed in the device wafer 310 as shown in FIG. 3E, by etching channels through the dielectric filler material 390 and forming openings through the underlying liner dielectric layer to expose contact areas on the upper surface of each device mesa 350. The channels may be selectively etched in certain positions using conventional masking and etching processes.

The size of the channels may be controlled to control the size of the contact areas on each device mesa 350.

Once the channels have been etched in the desired locations, metal is deposited into the etched channels, forming metal vias 410 which electrically connect the underlying semiconductor material to the planar upper surface 400 of the device wafer.

Metal vias 410 are preferably formed on each of the device mesas 350, but may also be formed in isolation trenches 360 and/or mesa trenches 370, as shown in FIG. 3E, depending on the electrical requirements of a given device.

As shown in FIG. 3F, additional layers of dielectric filler material and/or metal may be deposited to provide bonding pads 420 of appropriate shapes and sizes for bonding to a driver wafer 430.

FIG. 3G shows the device wafer 310 having been flipped upside-down and integrated with a driver wafer 430 to provide an integrated device. The driver wafer comprises a driver circuit for driving all of the LED device mesas 350, so that each metal via 410 in the device wafer 310 is electrically connected to a contact pad 450 in the driver circuit. The two wafers are bonded together using conventional wafer bonding techniques.

Once flipped upside down, the dielectric-lined mesa trenches 370 and isolation trenches 360 become barriers which separate the discrete device mesas 350.

The driver circuit (not shown) may take a variety of forms depending on the design requirements of any particular device, but preferably connects each LED device mesa to its own LED driver, so that the driver circuit is configured to drive each of the LED device mesas in the device wafer 310.

As shown in FIG. 3H, the substrate wafer 340 of the device wafer 310 may then be removed from the integrated device. When the substrate wafer 340 is removed, the remaining surface of the device wafer forms a light-emitting surface 460 of the device, with the porous layer 330 positioned between the light-emitting surface 460 and the device mesas 350. Additional non-porous layers (not shown) may be present between the light-emitting surface and the porous layer.

Further processing steps may then be carried out to process the device of FIG. 3H into an operable opto-electronic device 300. For example FIG. 3I shows micro-lenses 470 positioned over some of the LED device mesas to improve the optical emission properties of those LED device mesas. Metal pads 480 for wire bonding may also be deposited on the light-emitting surface, so that the metal pads are positioned over isolation trenches 360 and in electrical contact with the driver circuit through the metal vias 410 which extend through the isolation trench.

### Embodiment 2

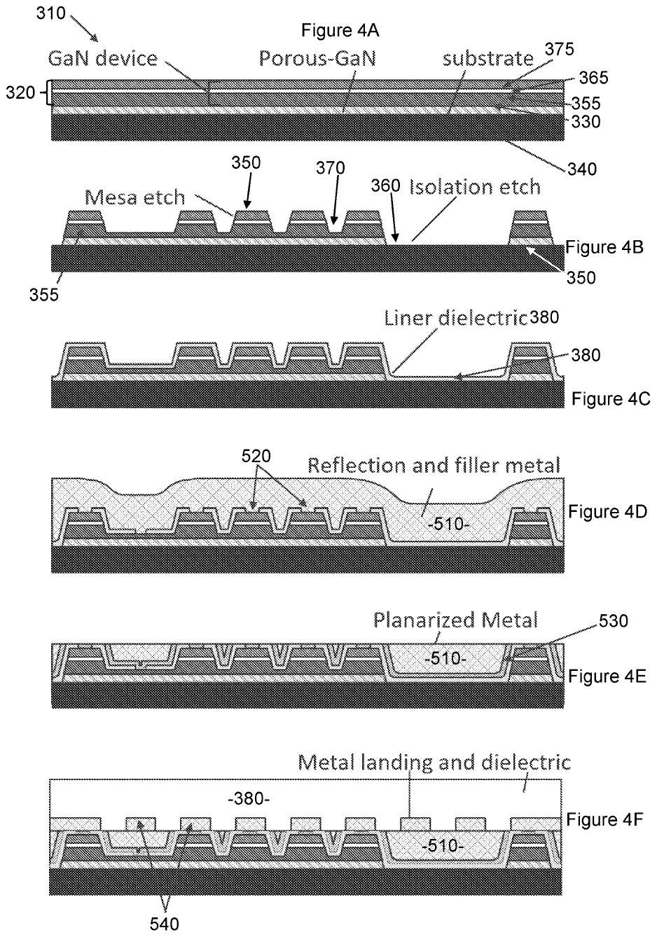

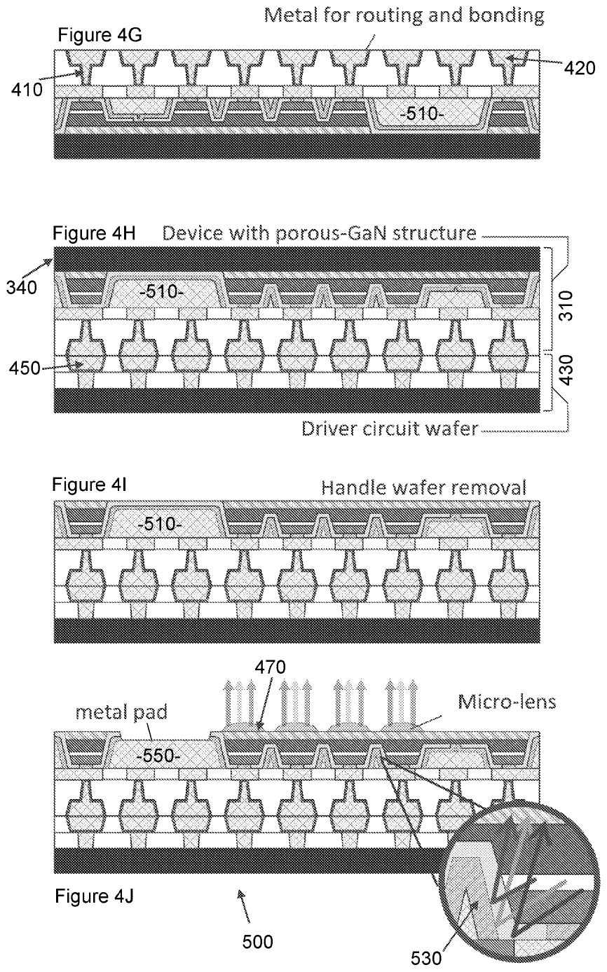

FIGS. 4A-4J are a step-by-step illustration of a method manufacturing an opto-electronic device 500 according to an alternative embodiment of the present invention.

The device wafer 310 shown in FIG. 4A may be the same as that described above with reference to FIG. 3A.

The steps in FIGS. 4A-4C are the same as those described above in relation to FIGS. 3A-3C.

In FIG. 4D, instead of depositing dielectric filler material 380 into the trenches to cover the device mesas 350, openings 520 may be etched through the liner dielectric layer 380 in the positions desired for electrical contacts. As discussed above, the sizes of the openings may differ between mesas in order to vary the contact areas on different device mesas.

After the openings 520 have been etched through the liner dielectric layer 380, metal 510 may be deposited over the device wafer to fill the openings 520 in the liner dielectric layer, cover the liner dielectric layer 380 and the device mesas 350. The metal 510 acts as a filler for the mesa trenches 370 and isolation trenches 360, and also creates a reflective layer 530 which surrounds and covers the LED device mesas 350.

As shown in FIG. 4E, the metal filler 510 is planarized level with the liner dielectric 380 on the tops of the mesas 350 so that the mesas are electrically isolated. As shown in FIG. 4F, metal pads 540 are then deposited on the planarized metal and the device mesas in the positions desired for electrical contacts, before covering the pads and the device wafer with dielectric filler material 380. The dielectric filler material 380 is then planarized to provide a flat, or planar, upper surface 400 on the device wafer.

Metal vias 410 are then formed in the device wafer as shown in FIG. 4G, by etching channels through the dielectric filler material 380 to reach the metal pads 540. The channels may be selectively etched in certain positions using conventional masking and etching processes.

As shown in FIG. 4G, additional layers of dielectric filler material and/or metal may be deposited to provide bonding pads 420 of appropriate shapes and sizes for bonding to a driver wafer 430.

FIG. 4H shows the device wafer 310 having been flipped upside-down and integrated with a driver wafer 430 to provide an integrated device. The driver wafer 430 comprises a driver circuit (not shown) for driving all of the LED device mesas, so that each metal via in the device wafer is electrically connected to a contact pad 450 in the driver circuit. The two wafers are bonded together using conventional wafer bonding techniques.

The driver circuit may take a variety of forms depending on the design requirements of any particular device, but preferably connects each LED device mesa to its own LED driver, so that the driver circuit is configured to drive each of the LED device mesas in the device wafer.

As shown in FIG. 4I, the substrate wafer 340 of the device wafer 310 may then be removed from the integrated device. When the substrate wafer is removed, the remaining surface of the device wafer forms a light-emitting surface 460 of the device, with the porous layer 330 positioned between the light-emitting surface 460 and the device mesas 350. Additional non-porous layers (not shown) may be present between the light-emitting surface and the porous layer.

Further processing steps may then be carried out to process the device of FIG. 4I into an operable opto-electronic device 500. For example FIG. 4J shows micro-lenses 470 positioned over some of the LED device mesas 350 to improve the optical emission properties of those LED device mesas. By etching an opening in the liner dielectric layer which lines the isolation trench, the metal filler material which fills the isolation trench may be turned into metal pads 550 for wire bonding.

In this embodiment, the embedded metal reflective layer 530 improves the light-extraction from the opto-electronic device by surrounding the light-emitting device mesas and reflecting any misdirected light up out of the light-emitting surface of the device.

### Porous Regions for Optical Enhancement

As mentioned above, the porous region, or porous layer, of the device wafer may take a variety of different forms depending on the application of a given device. The porous region may provide a variety of optical engineering functions to the device. For example the porous region may be configured to provide DBRs, alternating layers, optical filers, reflectors, band pass, band stop filters, and/or mirrors.

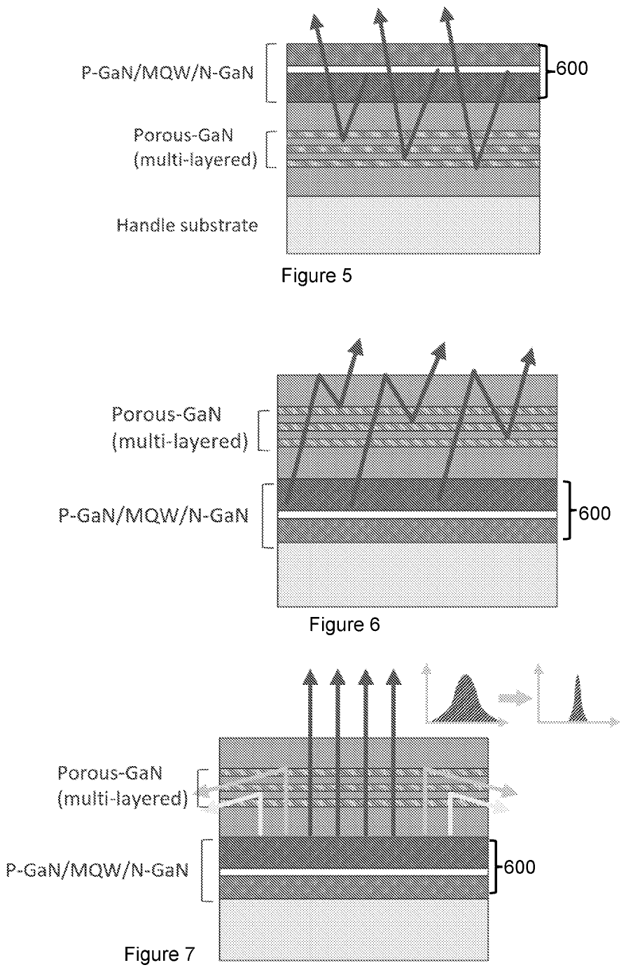

In FIGS. 5 to 9, the driver wafer and the rest of the device are not shown, and for simplicity only the porous region and an epitaxially-connected LED device mesa are shown.

Porous III-nitride material may advantageously be used to provide a variety of optical enhancement effects to the opto-electronic device. The porous region can be a single-layered or multi-layered structure, and the thickness, layer sequence and refractive index of each layer can be configured precisely and separately by controlling doping levels and layer design during epitaxial growth, and porosifying n-doped layers using the electrochemical porosification techniques in international patent applications PCT/GB2017/052895 (published as WO2019/063957) and PCT/GB2019/050213 (published as WO2019/145728).

FIG. 5 is a schematic illustration of a porous region of III-nitride material configured as a DBR for light extraction improvement in an optoelectronic device, according to a preferred embodiment of the present invention.

Due to the effect of porosity altering the refractive index of III-nitride material, porous III-nitride material may be used highly effectively to form distributed Bragg reflectors (DBRs) which selectively reflect certain wavelengths of light. The structure and manufacture of porous DBRs is described, for example, in international patent applications PCT/GB2017/052895 (published as WO2019/063957) and PCT/GB2019/050213 (published as WO2019/145728).

DBRs containing porous layers of III-nitride material may be formed on either side (above or below) the semiconductor device structure 600 which includes the light-emitting region. The DBR should be grown on the correct side of the light-emitting region to achieve the desired effect after the device wafer has been flipped and bonded to the driver wafer.

Where a DBR is positioned underneath the light-emitting region in the finished device, so that the light-emitting region is between the DBR and the light-emitting surface of the device, the DBR will function as a mirror which reflects any misdirected light back out of the light-emitting surface of the device. This significantly improves light-extraction, as emitted light is no longer directed towards the driver wafer and wasted.

The specific thickness and arrangement of the layers in the DBRs will differ depending on the wavelengths which are to be reflected and/or transmitted by the DBR.

FIG. 6 is a schematic illustration of a porous region of III-nitride material configured as an anti-reflection layer for light extraction improvement in an optoelectronic device, according to a preferred embodiment of the present invention. In this embodiment, a DBR is positioned between the light-emitting layer and the light-emitting surface of the device. Any emitted light which is undesirably reflected back into the device by reflection from the light-emitting surface will be reflected back out by the DBR, which enhances overall light

### Extraction

FIG. 7 is a schematic illustration of a porous region of III-nitride material configured as a colour filter for light extraction improvement in an optoelectronic device, according to a preferred embodiment of the present invention. The use of porous III-nitride material to optically filter emitted light is described in international patent application no. PCT/GB2021/052366 (published as WO2022/053831), and provides improved light extraction and narrower emission bandwidth by reflecting unwanted wavelengths and preventing their transmission out of the light-emitting surface of the device.

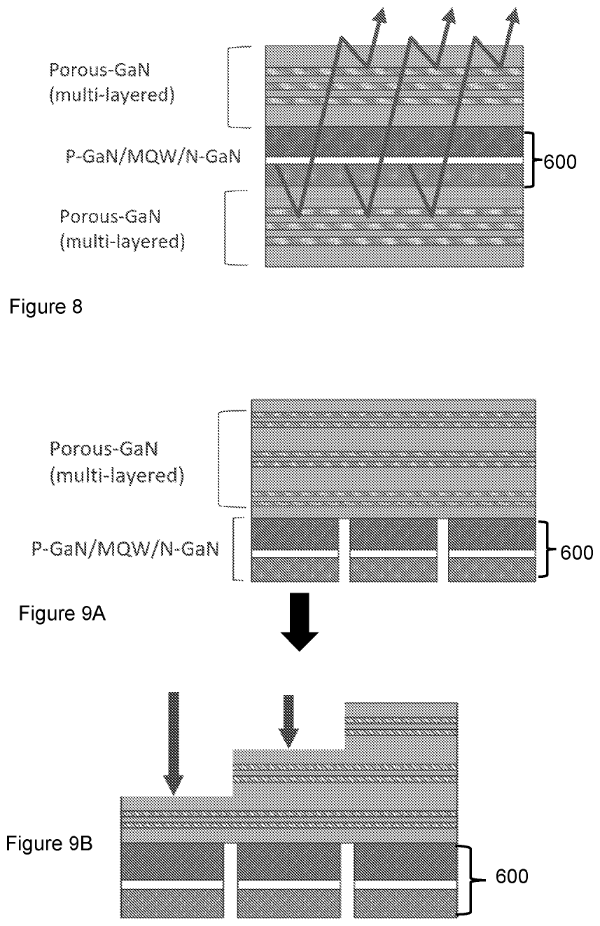

FIG. 8 is a schematic illustration of an optoelectronic device containing a porous III-nitride region on either side of the device structure acting as DBR/AF pairs, according to a preferred embodiment of the present invention. This embodiment combines the advantages of FIGS. 5 and 6, as one DBR reflects emitted light which is emitted in a direction away from the light-emitting surface of the device, while the other DBR acts as an anti-reflection coating which prevents emitted light from being reflected back into the device by the light-emitting surface.

FIGS. 9A and 9B are schematic illustrations of a multi-layered porous region of III-nitride material being etched into a multi-zone optical filter/AF layer. Rather than having a uniform porous region extending across the whole device wafer, and across multiple device mesas in the finished opto-electronic device, it is possible to tailor the porous region for specific device mesas.

FIG. 9A, for example, shows a uniform multi-layered porous region positioned over three separate LED device mesas. FIG. 9B then shows how selective etching of the porous region may be performed to alter the thickness of the porous region over selected device mesas. Thus the optical properties imparted by the porous region may be varied between device mesas. As each device mesa is preferably a pixel or subpixel of a display device, the porous region may be patterned to impart particular properties to some subpixels and different properties to others.

### Variable-Wavelength LEDS

In a particularly preferred embodiment of the present invention, the device epitaxial structure from which all of the device mesas are formed is a variable-wavelength LED epitaxial structure. Particularly advantageously, a single variable-wavelength LED epitaxial structure may be grown over a porous region of III-nitride material at wafer-scale to form a device wafer as shown in FIGS. 3A and 4A.

This entire wafer-scale device structure may be formed during a single epitaxial growth process, and then the method of the present invention may be used to process the resulting device wafer into an opto-electronic device in which each separate device mesa acts as a separate variable-wavelength LED.

This provides a large number of possibilities for a display device, as the “colour” (the peak emission wavelength) emitted by each LED can be controlled by controlling the driving current density provided to that particular LED mesa in use.

The driving circuit may thus be configured to drive the variable-wavelength LEDs in the device in a variety of ways depending on the desired result:
Each variable-wavelength LED in the device may be dynamically driven by the driving circuit, with each variable-wavelength LED receiving a drive current density the magnitude of which varies in real time during a display frame, so that the same variable-wavelength LED may be controlled to emit a plurality of different wavelengths during a single display frame.
Each variable-wavelength LED may be driven by the driving circuit with a fixed driving current density, so that the variable-wavelength LEDs behave as fixed-wavelength emitters in use. However, the driving circuit may be configured to provide driving current densities of different magnitudes to different variable-wavelength LEDs in the device. Even though the different variable-wavelength LEDs are formed from the same epitaxy and have the same device structure, the different driving current densities control different device mesas to emit different fixed peak emission wavelengths. Thus by providing different fixed drive conditions to different device mesas, a multi-colour display may be provided from a single device epitaxy.
A mixture of these two options may also be provided, with the driving circuit being configured to control some device mesas in the device dynamically, and to control other device mesas as fixed-wavelength emitters by providing a fixed driving current to those mesas.

During manufacturing, the size, shape and position of the variable-wavelength LEDs may be controlled by controlling the size, shape, depth and position of trenches etched into the device wafer.

By forming all of the separate device mesas from a single wafer epitaxy, it is possible to eliminate many of the time-consuming, low-yield and expensive processing steps required for device integration in the prior art.

In preferred embodiments of the present invention, the driving circuit and some or all of the variable-wavelength LEDs are preferably configured to receive a variable-magnitude supply of driving current from the driving circuit, so that the magnitude of the driving current to each variable-wavelength LED is variable. By varying the magnitude of the driving current to a variable-wavelength LED, the peak emission wavelength of that LED can be varied as the display device is used. The driving current provided to each variable-wavelength LED may be individually controllable, so that the peak emission wavelength of each variable-wavelength LED in the display may be controlled and varied individually. Alternatively, the device and the driving circuit may be configured so that the same driving conditions are provided to a group of variable-wavelength LEDs simultaneously, so that all of the variable-wavelength LEDs in that group emit light at the same peak emission wavelength when the driving current is on, and the peak emission wavelength of the entire group can be varied by varying the magnitude of the driving current.

In alternative embodiments, the driving circuit may be configured to provide a fixed-magnitude (i.e. non-variable) driving current, which is either on or off, to some or all of the variable-wavelength LEDs in the display device. When the fixed driving current is on, those variable-wavelength LEDs will behave as conventional LEDs, and emit at a single peak emission wavelength determined by the driving conditions provided to the LEDs. Thus variable-wavelength LEDs which are configured to receive a fixed-magnitude driving current may be used as fixed-emission-wavelength LEDs in the display device.

Preferably the driving circuit is configured to control at least one subpixel of each pixel as a dynamic variable-wavelength LED, the peak emission wavelength of which may be varied within a single display frame.

The driving circuit may be configured to separately control the driving current provided to each of the plurality of LEDs, so that each of the plurality of LEDs is individually driveable. The driving circuit may be configured to provide a plurality of different driving currents to the plurality of LEDs, so that separate LEDs are driveable to emit at different peak emission wavelengths in response to the different driving currents.

Alternatively, the driving circuit may be configured to separately control a groups of two or more LEDs, so that each LED in a group emits at the same peak emission wavelength. The driving circuit may be configured to provide different driving currents to different groups of LEDs, so that separate groups of LEDs are driveable to emit at different peak emission wavelengths in response to the different driving currents.

FIG. 10 is a series of five EL images of the same variable-wavelength MicroLED InGaN pixel being driven at different currents in constant wave mode (CW), showing five different colours of emission. In the left-hand image, the micro-LED emission colour is seen to be red at a driving current of 50 μA. In the second image from the left, the micro-LED emission colour is seen to be red-orange at a driving current of 100 μA. In the third image from the left, the micro-LED emission colour is seen to be orange at a driving current of 1 mA. In the fourth image from the left, the micro-LED emission colour is seen to be yellow-green at a driving current of 10 mA. In the right-hand image, the micro-LED emission colour is seen to be green at a driving current of 20 mA.

By varying the driving current between 50 μA to 20 mA, the same micro-LED is therefore capable of emitting at wavelengths ranging from red to green. The spectral width of this emission wavelength range is on the order of 90 nm (from around 570 nm to around 660 nm). This is a far greater range of emission wavelengths than has ever been achievable with a single LED in the prior art.

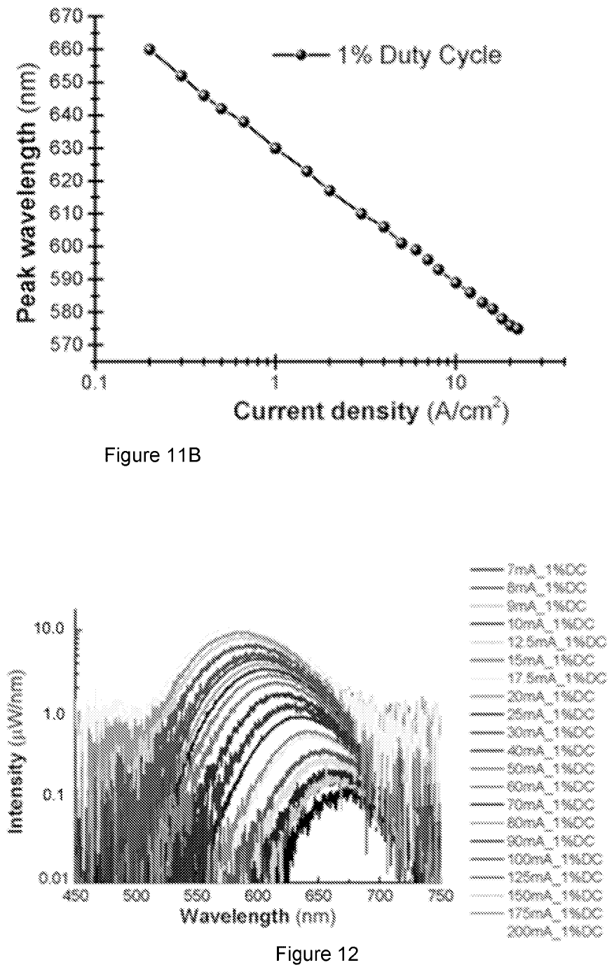

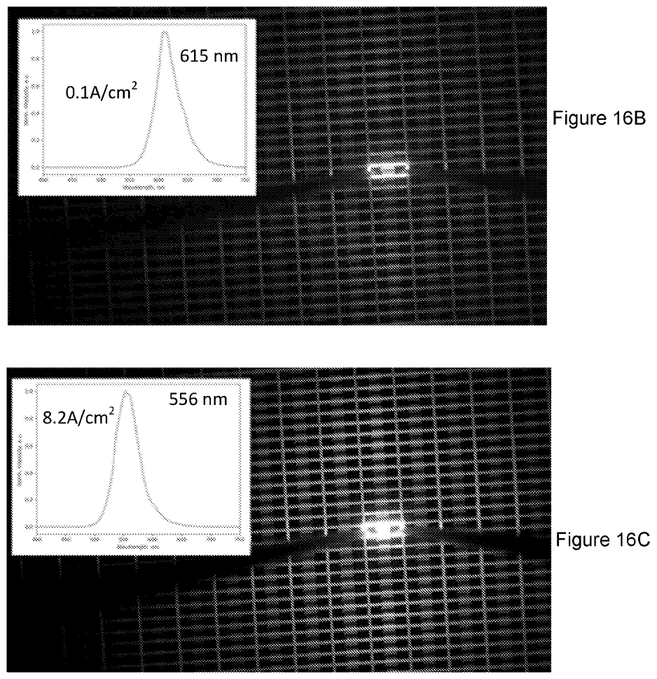

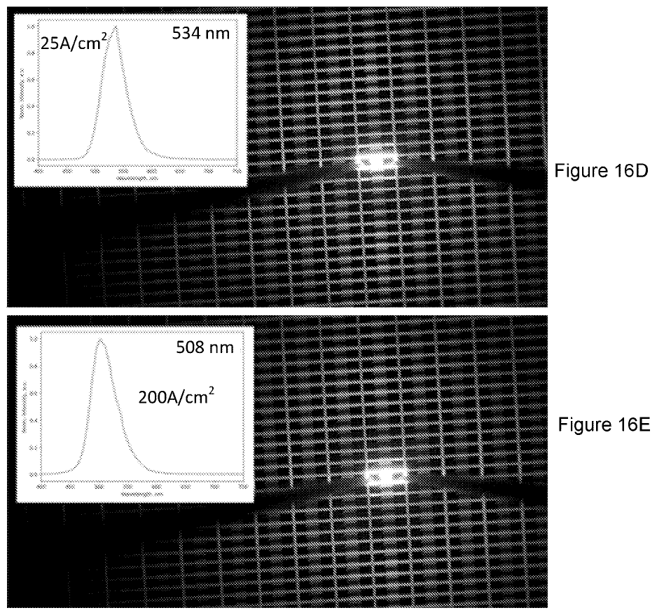

FIG. 11A is an emission wavelength vs current density plot for a 25 μm×25 μm InGaN LED pixel array (100×100 array, containing 10,000 pixels) driven in pulsed mode with a 100 μs pulse at 1% duty cycle. FIG. 16B is an emission wavelength vs current density plot for a 30 μm×30 μm InGaN LED pixel array (100×100 array, containing 10,000 pixels) driven in pulsed mode with a 100 μs pulse at 1% duty cycle.

Both of these plots show the controllability of the peak emission wavelength with a pulse driven power supply. In particular, the wavelength is linearly dependent on the current density (plotted on a logarithmic scale). This linearity can equally be manipulated when driving with a pulsed voltage power supply. The variable emission wavelengths of the LED can therefore be controlled with either voltage or current driving schemes in either CW or pulsed mode, all of which are standard ways of display driver IC.

This linear relationship between the driving current density and the resulting emission wavelength is highly advantageous for the purposes of LED display design, as it enables accurate control of the emission wavelengths by varying the current density of the power supply.

FIG. 12 is a plot of intensity vs wavelength for a variable-wavelength InGaN LED driven at different DC currents. The power supply is operated in pulsed driving mode with a 100 μs pulse at 1% duty cycle.

FIG. 12 again reflects a gradual, continuous transition of the peak emission wavelength of the LED as the current of the power supply is varied. At a driving current of 200 mA, the peak emission wavelength is around 575 nm, with an intensity of around 10 μW/nm. As the driving current is reduced, however, the peak emission wavelength moves gradually to longer wavelengths, and to lower emission intensities. When the driving current reaches 7 mA, the peak emission wavelength is approximately 675 nm, with an intensity of around 0.1 μW/nm.

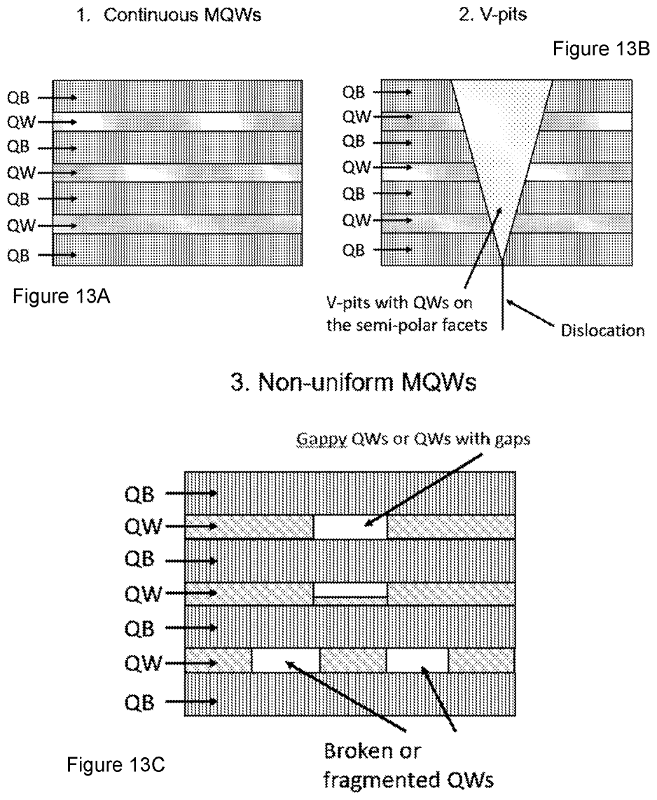

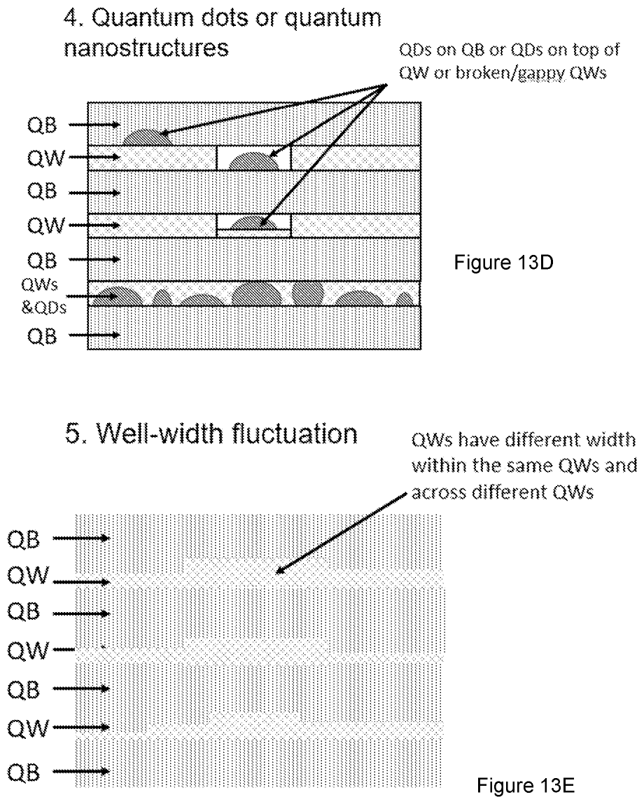

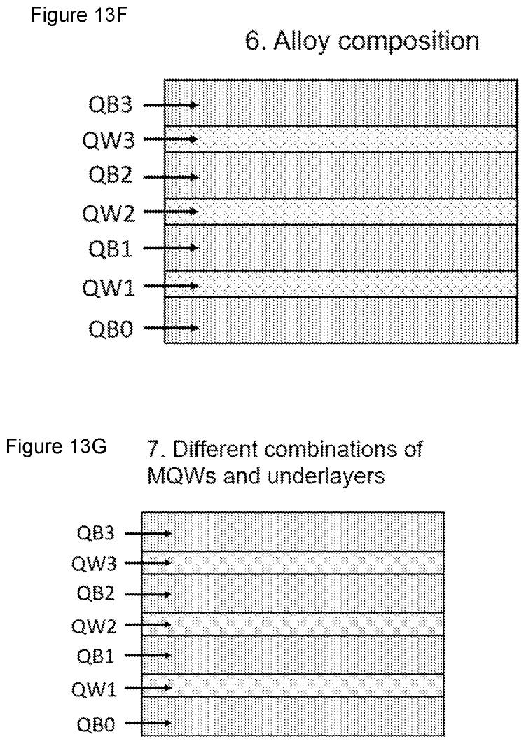

FIGS. 13A-G illustrate alternative embodiments of light-emitting regions of variable-wavelength LEDs which can be used as semiconductor devices in embodiments of the present invention.

### Examples of MQWs:

1. Continuous MQWs
2. V-pits
3. Broken QWs, gappy QWs, fragmented QWs
4. QDs
5. Well-width fluctuation
6. Alloy composition
7. Different combinations of MQWs and underlayers

These structural characteristics can be identified and examined by standard material characterisation techniques, such as cross-sectional transmission electron microscopy (TEM), X-ray diffraction (XRD), Energy Dispersive X-ray Spectroscopy (EDX or EDS), 3D atom probe (3DAP).

FIG. 13A shows a continuous MQW light-emitting region of an LED, in which three identical QWs are provided between four identical quantum barriers (QBs).

FIG. 13B shows the continuous MQW of FIG. 18A, with a V-shaped pit propagating through the light-emitting region. The v-shaped pit terminates in a threading dislocation, and has QWs on its semi-polar facets.

FIG. 13C shows a MQW in which the QW layers comprise discontinuities or gaps in the semiconductor material.

FIG. 13D shows a MQW in which quantum dots (QDs) create non-uniformities in the MQW. QDs may be provided on or in the QB or QW layers, for example in gaps in the QW structure.

FIG. 13E shows a MQW with well-width fluctuation, in which the thicknesses of the QW layers are not uniform across the light-emitting region. The QWs may have different widths from each other, and also varying widths within a single QW.

FIG. 13F shows a MQW with fluctuations in alloy composition in the light-emitting region. The compositions of the QBs and the QWs differ from layer to layer. In particular, the indium In % composition is varying within the same QWs, i.e. in QW2, In % is varying between 10-12% or 10-15%, or 10-25%, or 10-35%.

FIG. 13G shows a MQW containing different combinations of MQWs and underlayers. In % composition is different across different QWs. For example In % in QW1 is 15%, In % in QW2 is 25%, and In % in QW3 is 30%. In embodiments of the present invention, the lower In % QW is preferably positioned at the bottom of the MQW, due to its strain and thermal effect, while the high In % QWs is preferred to be on the top. In a preferred embodiment, for example, QW1 is a blue emitting QW, QW2 is a green emitting QW, QW3 is a red emitting QW.

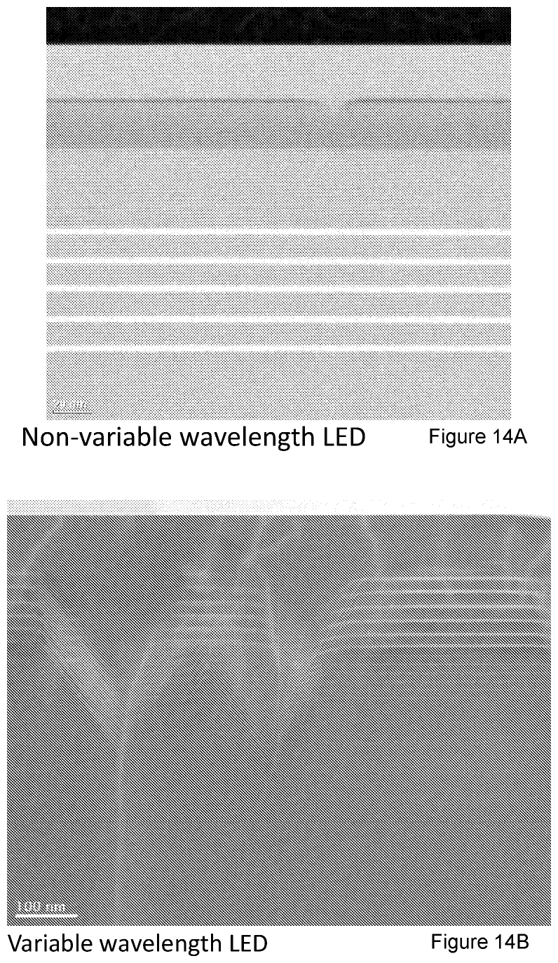

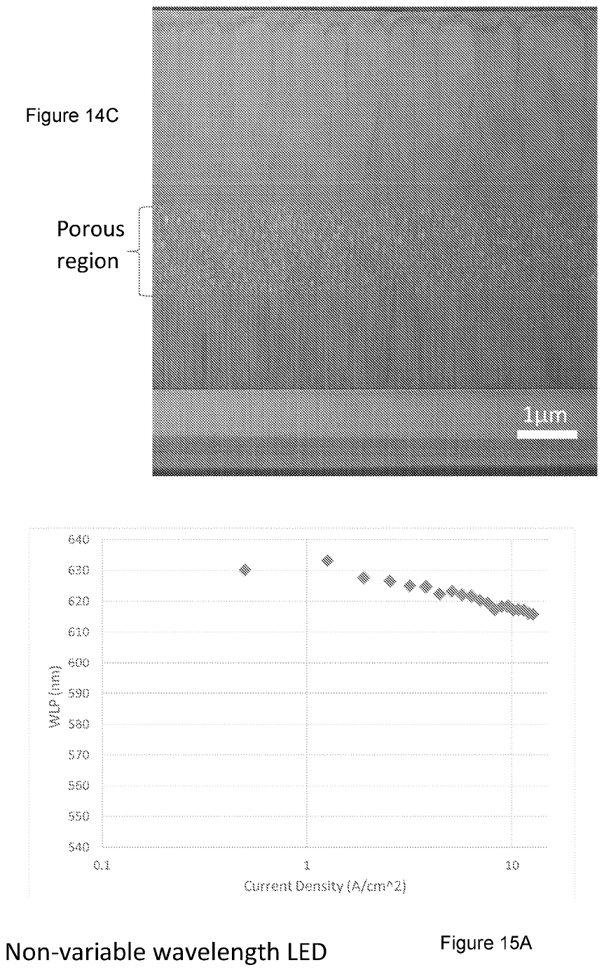

FIG. 14A is a TEM image of a cross-section of a conventional non-variable-wavelength LED. In this non-variable-wavelength LED, the MQWs are uniform and smooth in both upper and lower interface (5 MQWs shown here).

FIGS. 14B and 14C are TEM images a variable-wavelength LED comprising v-shaped pits, usable in an embodiment of the present invention. In this variable-wavelength LED, the MQWs are non-uniform. This non-uniformity can be induced by various methods, one example is v-pits and the semi-polar facets which would incorporate more indium and thinner QWs. Another example is also shown in FIG. 14B, that the MQWs are not uniform, in terms of broken QWs, discontinuous QWs, fragmented QWs, QWs with well-width or In composition fluctuation.

FIG. 14C shows a cross section of the variable-wavelength LED of FIG. 14B, showing a porous region and a light-emitting region comprising a plurality of v-shaped pits, usable in a preferred embodiment of the present invention.

In this structure, the light-emitting region contains multiple emission wavelength regions that are deliberately introduced such as multiple types of QW region with v-shaped pits extending through the light-emitting region.

V-shaped pits (V-pits) are actually hexagonal pits looking from the above, v-shape is when looking at the cross-section. V-pits can be initialize at each site of dislocations under special epitaxy growth conditions during the growth of InGaN, GaN, InGaN/InGaN superlattice, or InGaN/GaN superlattice structures underlying the MQWs, such as low growth temperature (e.g. <1000° C., or <900 C., or <800° C., or <700 C.) and nitrogen ambient.

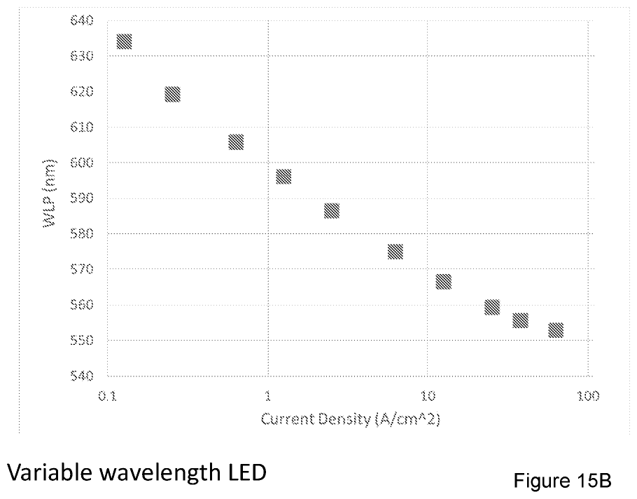

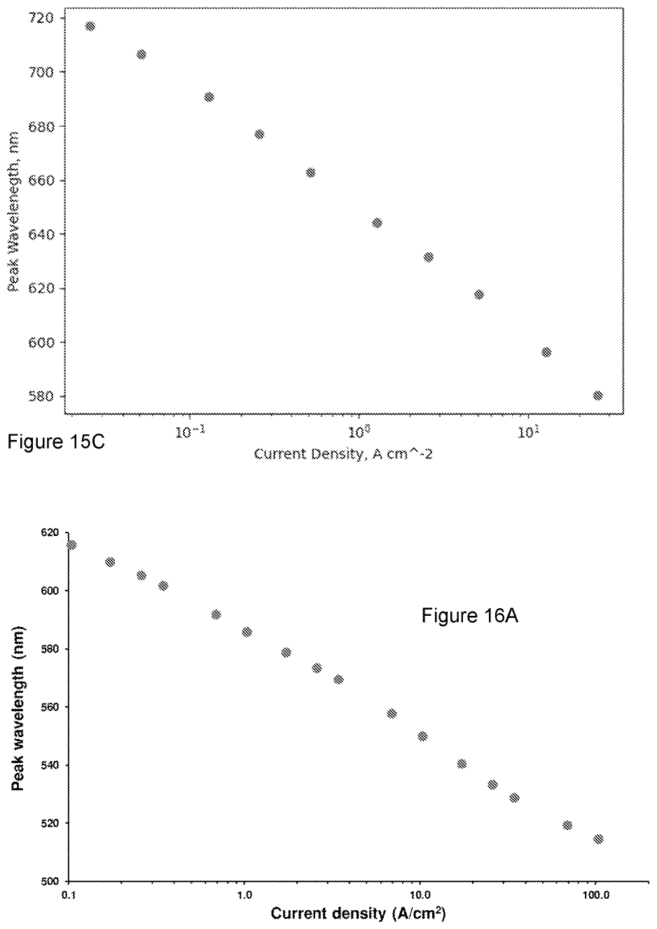

FIG. 15A is a graph of peak emission wavelength vs driving current density for a conventional non-variable wavelength LED. By varying the driving current density applied to the LED, the emission wavelength can be slightly varied, across an emission wavelength range of around 15 nm.

FIG. 15B is a graph of peak emission wavelength vs driving current density for a variable-wavelength LED usable as a first or second semiconductor device in embodiments of the present invention. In the variable-wavelength LED, varying the current density of the driving power supply creates a much larger variation in the peak emission wavelengths (WLP) emitted by the LED. In this embodiment, varying the driving current density between roughly 0.1 and 100 A/cm² varies the peak emission wavelength from around 635 nm to around 550 nm—an emission wavelength range of around 85 nm.

FIG. 15C is a graph of peak emission wavelength vs driving current density for a variable-wavelength LED according to another embodiment of the present invention. In this embodiment, varying the driving current density varies the peak emission wavelength from around 720 nm to around 580 nm—an emission wavelength range of around 140 nm.

FIG. 16A is a graph of peak emission wavelength vs driving current density for another variable-wavelength LED according to the present invention. In this embodiment, varying the driving current density between roughly 0.1 and 200 A/cm² varies the peak emission wavelength from 615 nm to 508 nm—an emission wavelength range of around 100 nm.

The data for this graph only goes to 514.5 nm due to a limitation on the testing capabilities. The current density for 508 nm is therefore estimated. However, the obtainable range of emission wavelengths can be pushed either way significantly.

FIGS. 16B-D are photographs of the variable-wavelength LED of FIG. 16A, showing the same variable-wavelength LED emitting at four different wavelengths across its emission wavelength range. The inset emission spectra show the different peak emission wavelengths at different driving current densities. This shows the same variable-wavelength LED emitting at peak emission wavelengths in the orange (615 nm), yellow (556 nm), green (534 nm) and blue (508 nm) in response to different driving current densities.

1. A method of manufacturing an opto-electronic device comprising the steps of:
providing a device wafer comprising an opto-electronic device epitaxial structure on a substrate wafer, the device epitaxial structure comprising a porous region of III-nitride material;
etching the device epitaxial structure into a plurality of device mesas;
depositing a liner dielectric layer over the plurality of device mesas;
forming a plurality of metal vias which extend through the liner dielectric layer to respective device mesas; and
bonding the device wafer to a driver wafer comprising a driver circuit, so that the driver circuit is operatively coupled to the plurality of device mesas through the metal vias.

2. A method according to claim 1, in which the device wafer is bonded to the driver wafer so that each metal via is electrically coupled to its own CMOS driver in the driver circuit.

3. A method according to claim 1 or 2, comprising the step of depositing dielectric filler material over the plurality of device mesas after the liner dielectric layer has been deposited, to provide a planar upper surface on the device wafer; in which the metal vias extend from the planar upper surface, through the dielectric filler material and the liner dielectric layer to respective device mesas, and in which the planar upper surface of the device wafer is bonded to the driver wafer.

4. A method according to claim 3, comprising the step of depositing the dielectric filler material directly over the liner dielectric layer.

5. A method according to claim 3 or 4, in which the step of forming the metal vias comprises etching a plurality of channels from the planar upper surface of the wafer, through the dielectric filler material and the liner dielectric layer, to the device mesas, and then depositing metal in the plurality of channels to form metal vias.

6. A method according to any of claims 1 to 5, comprising the step of depositing a reflective layer over the plurality of device mesas following the step of depositing the liner dielectric layer over the plurality of device mesas, preferably in which the reflective layer is a metal layer.

7. A method according to claim 6, in which the reflective layer is formed by depositing metal over the liner dielectric layer to fill trenches between device mesas, and comprising the step of planarizing the metal level with the liner dielectric layer extending over the top of the device mesas.

8. A method according to claim 6, comprising the step of depositing a reflective layer and then depositing metal filler material over the reflective layer, and planarizing the metal filler material level with the liner dielectric layer extending over the device mesas prior to the step of depositing dielectric filler material.

9. A method according to any of claims 6 to 8, comprising the step of, prior to depositing the reflective layer, etching a plurality of openings through the liner dielectric layer over the plurality of device mesas.

10. A method according to claim 9, comprising the step of depositing a metal pad over each of the openings in the liner dielectric layer, the metal pads forming electrical contacts for each of the device mesas.

11. A method according to claim 10, comprising the step of depositing dielectric filler material over the plurality of device mesas after the metal pads have been deposited, to provide a planar upper surface on the device wafer; in which the metal vias extend from the planar upper surface, through the dielectric filler material to respective metal pads, and in which the planar upper surface of the device wafer is bonded to the driver wafer.

12. A method according to claim 11, in which the step of forming the metal vias comprises etching a plurality of channels from the planar upper surface of the wafer, through the dielectric filler material, to the metal pads, and then depositing metal in the plurality of channels to form metal vias.

13. A method according to any preceding claim, in which the step of etching the device epitaxial structure into a plurality of device mesas comprises performing an isolation etch, in which an isolation trench is etched through the entire depth of the device epitaxial structure, to electrically isolate device mesas on opposite sides of the isolation trench.

14. A method according to claim 13, comprising the step of forming one or more metal vias in an isolation trench.

15. A method according to claim 13 or 14, in which the isolation trench metal via extends from the planar wafer surface, through the dielectric filler material and the liner dielectric layer, to the substrate wafer.

16. A method according to claim 13 or 14, in which the isolation trench metal via extends from the planar wafer surface, through a dielectric filler material, to a metal pad in the isolation trench.

17. A method according to any preceding claim, in which the step of etching the device epitaxial structure into a plurality of device mesas comprises performing a mesa etch, in which a mesa trench is etched through a partial depth of the device epitaxial structure, the mesa trench not extending through at least one electrically conductive layer of the device wafer, such that device mesas on either side of the mesa trench are not electrically isolated from one another.

18. A method according to claim 17, comprising the step of forming one or more metal vias in a mesa trench.

19. A method according to claim 17 or 18, comprising the step of etching one or more openings through the liner dielectric area in a mesa trench to expose a layer of the device epitaxial structure below the liner dielectric layer.

20. A method according to claim 17, 18 or 19, in which the mesa trench metal via extends from the planar wafer surface, through the dielectric filler material and the liner dielectric layer, to a layer of device epitaxial structure below the mesa trench.

21. A method according to any preceding claim, comprising the step of depositing, over the metal vias, a plurality of metal pads for routing and bonding to the driver wafer.

22. A method according to any preceding claim, in which the method comprises the step of removing the substrate wafer to form a light-emitting-side of the device after the device wafer is bonded to the driver wafer.

23. A method according to claim 22, comprising the step of etching an opening through the liner dielectric layer to the isolation trench after removal of the substrate wafer, to expose metal in the isolation trench, the exposed metal in the isolation trench forming a metal pad for wire bonding.

24. A method according to claim 22, comprising the step of depositing a metal pad over an isolation trench after removal of the substrate wafer, the metal pad being in electrical connection with one or more metal vias extending through the device to the driver wafer.

25. A method according to any of claims 22, 23 or 24, comprising the step of depositing one or more micro-lenses over some or all of the device mesas on the light-emitting-side of the device.

26. A method according to any preceding claim, in which the device epitaxial structure is an LED structure, such that each device mesa is an LED, preferably a mini-LED, micro-LED or nano-LED structure.

27. A method according to any preceding claim, in which the device wafer comprises a porous region of III-nitride material positioned between the device epitaxial structure and the substrate wafer.

28. A method according to any preceding claim, in which the device wafer comprises a porous region of III-nitride material positioned in the device epitaxial structure.

29. An opto-electronic device comprising:
a driver wafer comprising a driver circuit;
a plurality of opto-electronic device mesas, each device mesa being configured to emit light out of a light-emitting-side of the device in response to a driving current from the driver circuit;
a porous region of III-nitride material epitaxially connected to one or more of the device mesas; and
a liner dielectric layer positioned between the driver wafer and the device mesas;
each opto-electronic device mesa being operatively coupled to the driver circuit by a plurality of metal vias which extend through the liner dielectric layer.

30. An opto-electronic device according to claim 29, comprising a dielectric filler material positioned between the driver wafer and the liner dielectric layer; in which the metal vias extend through the dielectric filler material and the liner dielectric layer.

31. An opto-electronic device according to claim 29 or 30, in which each device mesa has the same device epitaxial structure.

32. An opto-electronic device according to claim 29, 30 or 31, in which the device epitaxial structure comprises an n-doped region, a p-doped region, and a light-emitting region arranged between the n-doped region and the p-doped region.

33. An opto-electronic device according to any of claims 29 to 32, in which each device mesa is electrically coupled to its own CMOS driver in the driver circuit, such that each device mesa is independently driveable by the driver circuit.

34. An opto-electronic device according to any of claims 29 to 33, in which different device mesas have different lateral sizes, such that different device mesas have light-emitting areas of different sizes.

35. An opto-electronic device according to any of claims 29 to 34, in which the device comprises two or more device mesas which are electrically connected to one another via a shared conductive layer of semiconductor material.

36. An opto-electronic device according to claim 35, in which electrically-connected device mesas are separated by mesa barriers positioned between device mesas, in which the mesa barriers do not extend through the shared conductive layer.

37. An opto-electronic device according to claim 35 or 36, in which the shared conductive layer is an n-type layer or a p-type layer forming part of the device epitaxial structure, a doped connecting layer connected to multiple device mesas, or a porous layer of semiconductor material connected to multiple device mesas.

38. An opto-electronic device according to claim 35, 36 or 37, in which the mesa barriers are formed from dielectric filler material covered by the liner dielectric layer.

39. An opto-electronic device according to claim 35, 36 or 37, in in which the mesa barriers are formed from metal covered by the liner dielectric layer.

40. An opto-electronic device according to any of claims 29 to 39, in which the device comprises two or more device mesas which are electrically isolated from one another.

41. An opto-electronic device according to claim 40, in which electrically isolated device mesas are separated by electrically-insulating isolation barriers.

42. An opto-electronic device according to claim 41, in which the isolation barriers are formed from dielectric filler material covered by the liner dielectric layer.

43. An opto-electronic device according to claim 41, in which the isolation barriers are formed from a metal pad surrounded by the liner dielectric layer.

44. An opto-electronic device according to any of claims 29 to 39, in which the device comprises a reflective layer adjacent to the liner dielectric layer, the reflective layer being positioned between the liner dielectric layer and the driver wafer.

45. An opto-electronic device according to claim 41, in which the reflective layer surrounds the sidewalls of the device mesas to form a sidewall reflection structure configured to reflect emitted light towards the light-emitting-side of the device.

46. An opto-electronic device according to any of claims 29 to 45, in which the device comprises a plurality of micro-lenses arranged on a light-emitting-side of the device, each micro-lens being positioned over a respective device mesa and configured to transmit light emitted by the underlying opto-electronic device mesa.

47. An opto-electronic device according to any of claims 29 to 46, in which the device comprises one or more metal pads on the light-emitting side of the device, each metal pad being electrically connected to the driver circuit by one or more metal vias.

48. An opto-electronic device according to any of claims 29 to 47, in which the device is a display device, and in which each device mesa is preferably a mini-LED, micro-LED or nano-LED.

49. An opto-electronic device according to any of claims 29 to 48, in which some or all of the device mesas are variable-wavelength LEDs configured to emit a variable peak emission wavelength in response to variations in the driving current provided to the LED, in which the peak emission wavelength of the LED is continuously controllable over an emission wavelength range of at least 40 nm by varying the driving current to the LED.

50. An opto-electronic device according to claim 49, in which the peak emission wavelength is variable over an emission wavelength range of at least 50 nm, or at least 60 nm, or at least 70 nm, or at least 80 nm by varying the driving current, preferably over a range of up to 100 nm or 110 nm or 120 nm or 140 nm, or 160 nm, or 180 nm, or 200 nm, or 400 nm, or 450 nm.

51. An opto-electronic device according to claim 49 or 50, in which the driver circuit is configured to supply a variable-magnitude driving current to the variable-wavelength LED device mesas, to vary the peak emission wavelength of the variable-wavelength LED device mesas.

52. An opto-electronic device according to any of claims 29 to 48, in which the device comprises a monolithic array of LED device mesas, in which each device mesa is an LED subpixel, and in which groups of LED device mesas form a device pixel.

53. An opto-electronic device according to any of claims 29 to 48, comprising one or more porous regions of III-nitride material.

54. An opto-electronic device according to claim 53, in which each device mesa comprises its own porous region of III-nitride material, or in which a shared porous region is epitaxially connected to a plurality of device mesas.

55. An opto-electronic device according to claim 53 or 54, in which the device comprises a porous region of III-nitride material positioned over the device mesas, between some or all of the device mesas and the light-emitting surface of the device.

56. An opto-electronic device according to claim 53, 54 or 55, in which the device wafer comprises a distributed Bragg reflector (DBR) positioned over the device mesas, such that the device mesas are arranged between the DBR and the light-emitting surface of the device, the DBR comprising a plurality of porous layers of III-nitride material, the DBR being configured to act as an optical filter which transmits a first emitted wavelength of light and reflects other emitted wavelengths.

57. An opto-electronic device according to claim 53, 54, 55 or 56, in which the porous region is configured to act as an anti-reflection layer on the light-emitting side of the device.

58. An opto-electronic device according to claim 53 or 54, in which the device comprises a porous region of III-nitride material positioned between some or all of the device mesas and the driver wafer.

59. An opto-electronic device according to claim 58, in which the device comprises a distributed Bragg reflector (DBR) positioned between the device mesas and the driver wafer, the DBR comprising a plurality of porous layers of III-nitride material, the DBR being configured to reflect emitted light out of the light-emitting-side of the device.

60. An opto-electronic device according to any of claims 53 to 59, in which the or each porous region in the device has the same thickness and porosity.

61. An opto-electronic device according to any of claims 53 to 59, in which the device comprises a plurality of porous regions having different thicknesses and/or porosities, such that different device mesas are aligned with different porous regions.

62. An opto-electronic device according to claim 61, in which the porosity characteristics of the porous region varies in different lateral locations on the device.

63. An opto-electronic device according to claim 62, in which a first porous region has a first thickness, and a second porous region in a separate lateral location in the device has a second thickness different from the first thickness.

64. An opto-electronic device according to claim 62 or 63, in which the device comprises a multi-zone optical filter comprising a plurality of porous regions of different thicknesses, the respective porous regions of different thicknesses being positioned over different device mesas.

65. An opto-electronic device according to any of claims 53 to 64, in which the porous region comprises a stack of layers of porous III-nitride material, and optionally one or more layers of non-porous III-nitride material in between layers of porous III-nitride material.
